(19) United States
(12) Patent Application Publication
(10) Pub. No.: US 2025/0062229 A1
(43) Pub. Date: Feb. 20, 2025

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Changhee Lee, Suwon-si (KR); Chulmin Choi, Suwon-si (KR); Sangyong Park, Suwon-si (KR); Dajin Kim, Suwon-si (KR); Taeho Kim, Suwon-si (KR); Gunwook Yoon, Suwon-si (KR); Taehun Kim, Suwon-si (KR); Seungjae Baik, Suwon-si (KR); Jaeduk Lee, Suwon-si (KR)

(21) Appl. No.: 18/660,743

(22) Filed: May 10, 2024

(30) Foreign Application Priority Data
Aug. 18, 2023 (KR) 10-2023-0108420

(51) Int. Cl. H01L 23/528; H01L 25/065; H10B 41/10; H10B 41/27; H10B 41/35; H10B 43/10; H10B 43/27; H10B 43/35; H10B 80/00

(52) U.S. Cl. CPC H01L 23/5283; H01L 25/0652; H10B 41/10; H10B 41/27; H10B 41/35; H10B 43/10; H10B 43/27; H10B 43/35; H10B 80/00; H01L 2225/06506

(57) ABSTRACT

A semiconductor device includes a first semiconductor structure that includes a first substrate, circuit devices on the first substrate, a lower interconnection structure, and a lower bonding structure; and a second semiconductor structure disposed on and connected to the first semiconductor structure The second semiconductor structure includes a stack structure; channel structures that including a first portion that penetrate through the stack structure in the vertical direction and a second portion that extends upward from the first portion; a first material layer disposed on the stack structure and the channel structure and having first conductivity; and a second material layer disposed between the first material layer and the stack structure and having second conductivity., The first material layer overlaps second portions of the channel structures in the vertical direction, and the second material layer does not overlap the second portions of the channel structures in the vertical direction.

### CROSS-REFERENCE TO RELATED APPLICATION(S)

This application claims priority under 35 U.S.C. 119 (a) from Korean Patent Application No. 10-2023-0108420, filed on Aug. 18, 2023 in the Korean Intellectual Property Office, the contents of which are herein incorporated by reference in their entirety.

### TECHNICAL FIELD

Embodiments of the present disclosure are directed to a semiconductor device and a data storage system that includes the same.

### DISCUSSION OF THE RELATED ART

A semiconductor device should be able to store high-capacity data in a data storage system. Accordingly, a method for increasing data storage capacity of a semiconductor device has been researched. For example, as a method for increasing data storage capacity of a semiconductor device, a semiconductor device that includes memory cells disposed three-dimensionally, instead of memory cells disposed two-dimensionally, has been suggested.

### SUMMARY

An embodiment of the present disclosure provides a semiconductor device that has increased electrical properties and reliability and that can be easily manufactured.

An embodiment of the present disclosure provides a data storage system that includes a semiconductor device that has increased electrical properties and reliability and that can be easily manufactured.

According to an embodiment of the present disclosure, a semiconductor device includes a first semiconductor structure that includes a first substrate, circuit devices disposed on the first substrate, a lower interconnection structure that is electrically connected to the circuit devices, and a lower bonding structure connected to the lower interconnection structure; and a second semiconductor structure disposed on and connected to the first semiconductor structure. The second semiconductor structure includes a stack structure that includes interlayer insulating layers and gate electrodes stacked in a vertical direction; channel structures that each include a first portion that penetrates through the stack structure in the vertical direction and a second portion that extending upward from the first portion; an upper interconnection structure disposed below the stack structures; an upper bonding structure connected to the upper interconnection structure and bonded to the lower bonding structure; a first material layer disposed on the stack structure and the channel structure and that has a first conductivity; and a second material layer disposed between the first material layer and the stack structure and that has a second conductivity that differs from the first conductivity. The first material layer overlaps the second portion of the channel structures in the vertical direction, and the second material layer does not overlap the second portion of the channel structures in the vertical direction.

According to an embodiment of the present disclosure, a semiconductor device includes a stack structure that includes interlayer insulating layers and gate electrodes stacked in a vertical direction; a first material layer disposed on the stack structure and that includes a first semiconductor material that has a first conductivity; a second material layer disposed between the first material layer and the stack structure and that includes a second semiconductor material that has a second conductivity that differs from the first conductivity; a channel structure that includes a first portion that penetrates through the stack structure in the vertical direction, and a second portion that extends upward from the first portion, penetrates through the second material layer, and is disposed below the first material layer; and a buffer layer disposed between the second portion of the channel structures and the second material layer, and between the second portion of the channel structures and the first material layer.

According to an embodiment of the present disclosure, a data storage system includes a semiconductor storage device that includes a first semiconductor structure that includes a substrate and circuit devices disposed on the substrate; a second semiconductor structure that includes a stack structure that includes interlayer insulating layers and gate electrodes stacked in a vertical direction and channel structures that penetrate through the stack structure; and input/output pad electrically connected to the circuit devices; and a controller that is electrically connected to the semiconductor storage device through the input/output pad and that controls the semiconductor storage device. The first semiconductor structure further includes a lower interconnection structure that is electrically connected to the circuit devices; and a lower bonding structure connected to the lower interconnection structure. The second semiconductor structure includes an upper interconnection structure disposed below the stack structure; an upper bonding structure connected to the upper interconnection structure and bonded to the lower bonding structure; a first material layer disposed on the stack structure and the channel structure and that has a first conductivity; and a second material layer disposed between the first material layer and the stack structure and that has a second conductivity that differs from the first conductivity. Each of the channel structures includes a first portion that penetrates through the stack structure in the vertical direction and a second portion that extends upward from the first portion, where the first material layer overlaps second portion of the channel structures in the vertical direction, and the second material layer does not overlap the second portion of the channel structures in the vertical direction.

### BRIEF DESCRIPTION OF THE DRAWINGS

FIG. 1 is an exploded perspective view of a semiconductor device according to an embodiment of the present disclosure.

FIGS. 2A to 2C are plan views of a semiconductor device according to an embodiment of the present disclosure.

FIGS. 3A and 3B are cross-sectional views of a semiconductor device according to an embodiment of the present disclosure.

FIG. 3C is enlarged cross-sectional view of a portion of a semiconductor device according to an embodiment of the present disclosure.

FIGS. 4A to 4C are enlarged cross-sectional views of a portion of a semiconductor device according to an embodiment of the present disclosure.

FIG. 5 is an exploded perspective view of gate electrodes of a semiconductor device according to an embodiment of the present disclosure.

FIGS. 6 and 7 are cross-sectional views of a semiconductor device according to an embodiment of the present disclosure.

FIGS. 8A to 8K are cross-sectional views that illustrate a method of manufacturing a semiconductor device according to an embodiment of the present disclosure.

FIG. 9 illustrates a data storage system that includes a semiconductor device according to an embodiment of the present disclosure.

FIG. 10 is a perspective view of a data storage system that includes a semiconductor device according to an embodiment of the present disclosure.

FIG. 11 is a cross-sectional view of a semiconductor package according to an embodiment of the present disclosure.

### DETAILED DESCRIPTION

Hereinafter, embodiments of the present disclosure will be described as follows with reference to the accompanying drawings.

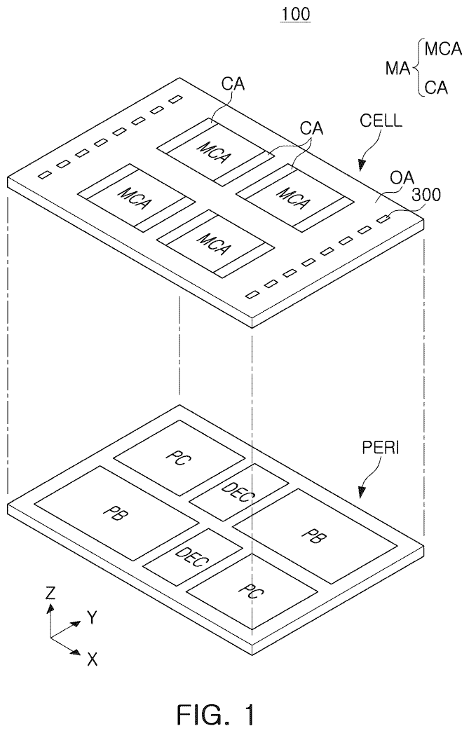

FIG. 1 is an exploded perspective view of a semiconductor device according to an embodiment.

Referring to FIG. 1, a semiconductor device 100 according to embodiments includes a peripheral circuit region PERI and a memory cell region CELL stacked in the vertical direction Z. The peripheral circuit region PERI and memory cell region CELL are bonded and coupled to each other. The memory cell region CELL includes a memory region MA that includes a memory cell array region MCA and a connection region CA, and an external side region OA disposed on an side of the memory region MA. A conductive pad 300, which is an input/output pad, is disposed on the external side region OA. A plurality of memory regions MA that include the memory cell array region MCA and the connection region CA are disposed.

The peripheral circuit region PERI includes a raw decoder DEC, a page buffer PB and a peripheral circuit PC. In the peripheral circuit region PERI, the raw decoder DEC generates driving signals for a wordline by decoding an input address and transmits the signals. The page buffer PB is connected to the memory cell array region MCA through bitlines, and reads data stored in memory cells. The peripheral circuit PC includes a control logic and a voltage generator, and may include, for example, a latch circuit, a cache circuit, and/or a sense amplifier. The peripheral circuit region PERI further includes a pad region, and the pad region includes an electrostatic discharge (ESD) device or a data input/output circuit. The ESD element or data input/output circuit of the pad region are electrically connected to the conductive pad 300 of the external side region PA. The various circuit regions DEC, PB, and PC in the peripheral circuit region PERI may be disposed in various forms.

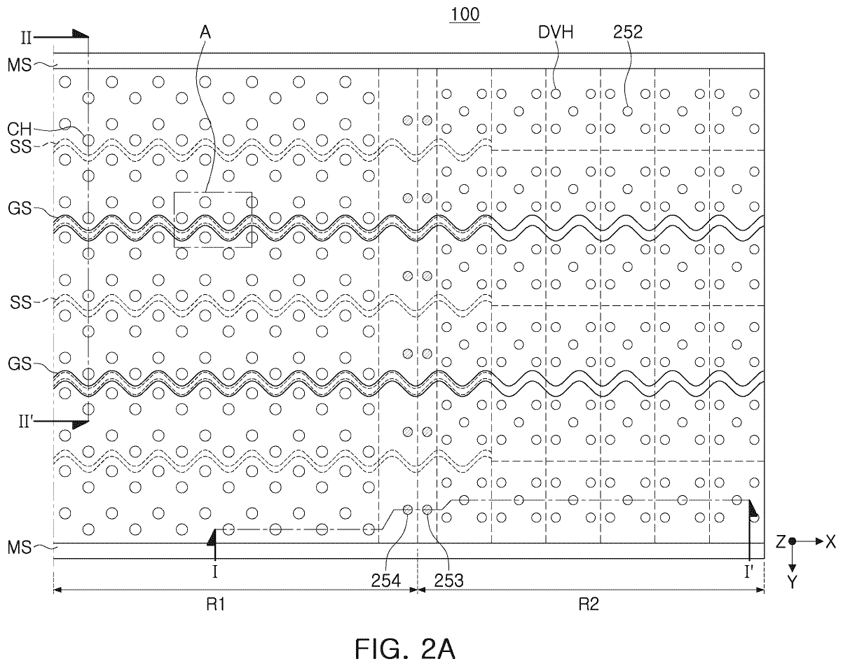

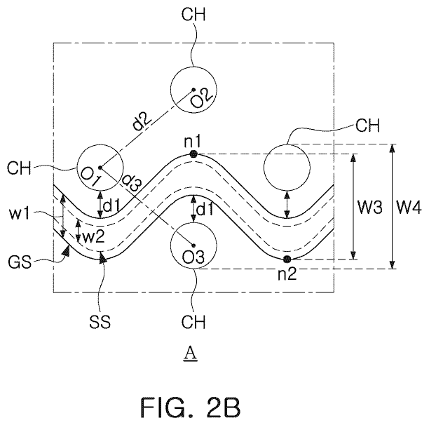

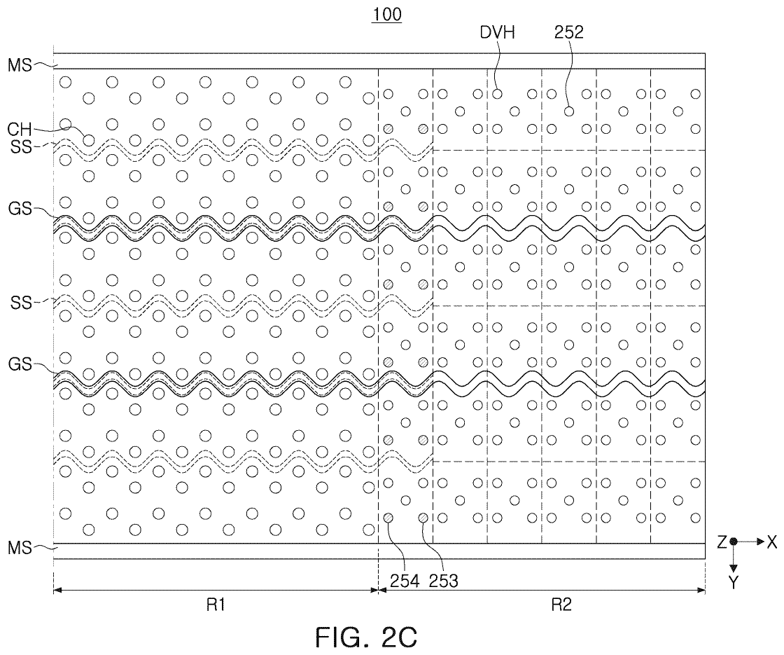

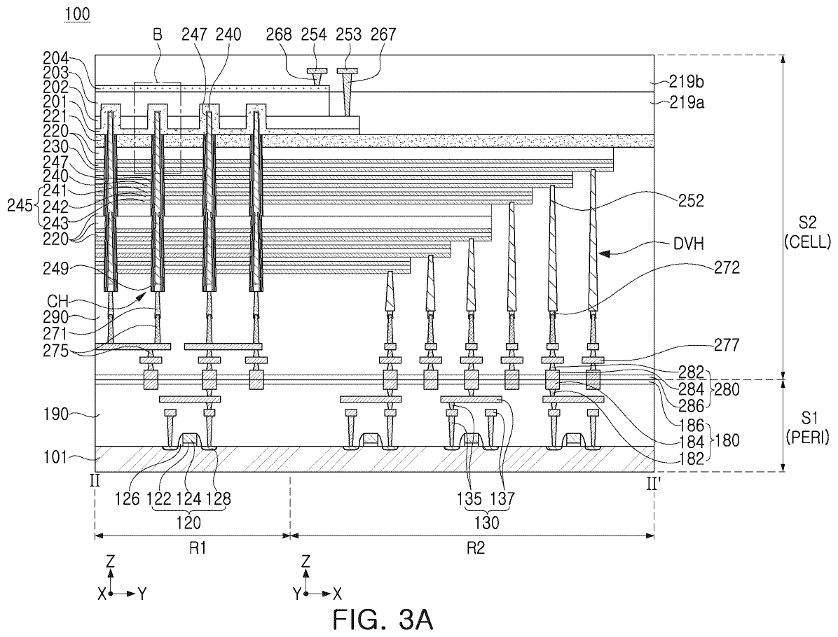

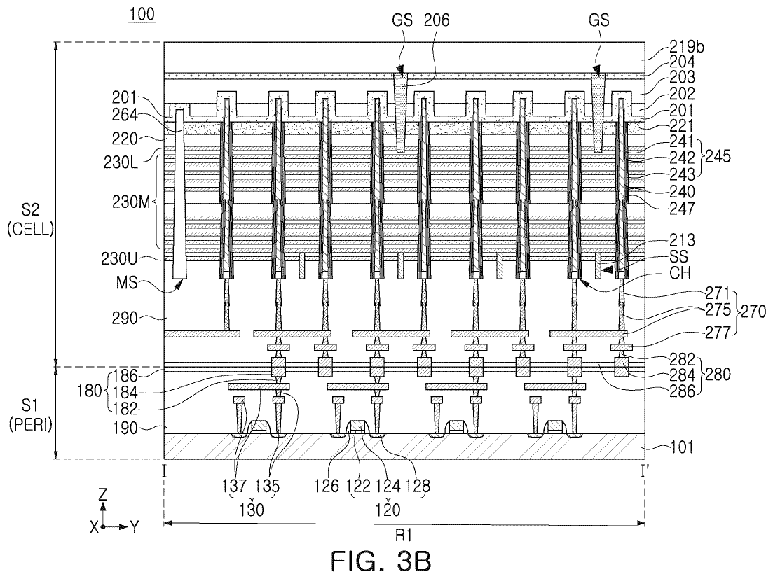

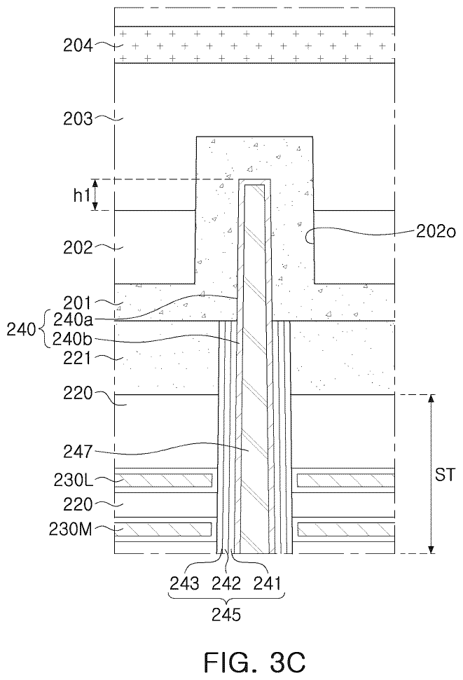

Hereinafter, an example of the semiconductor device 100 will be described in greater detail with reference to FIGS. 2A to 3C.

FIGS. 2A to 2C are plan views that illustrate a semiconductor device according to an embodiment, and FIG. 2B is an enlarged view of region “A” in FIG. 2A.

FIGS. 3A to 3C are cross-sectional views of a semiconductor device according to an embodiment, FIGS. 3A and 3B are cross-sectional views taken along cutting lines I-I′ and II-II′ of FIG. 2A, respectively, and FIG. 3C is an enlarged view of region “B” in FIG. 3A.

In FIG. 2A, a first region R1 correspond to the memory cell array region MCA illustrated in FIG. 1, and a second region R2 may correspond to the connection region CA illustrated in FIG. 1.

Referring to FIGS. 3A and 3B, in an embodiment, the semiconductor device 100 includes a peripheral circuit region PERI and a memory cell region CELL. The memory cell region CELL is disposed on the peripheral circuit region PERI. The peripheral circuit region PERI and the memory cell region CELL are bonded to each other through bonding structures 180 and 280. The peripheral circuit region PERI may be referred to as the first semiconductor structure S1, and the memory cell region CELL may be referred to as the second semiconductor structure S2.

The peripheral circuit region PERI includes a first substrate 101, circuit devices 120 on the first substrate 101, a lower interconnection structure 130, a lower bonding structure 180, and a lower capping layer 190.

The first substrate 101 includes a semiconductor material, such as one of a group IV semiconductor, a group III-V compound semiconductor, or a group II-VI compound semiconductor. The first substrate 101 may be provided as a bulk wafer or an epitaxial layer. In the first substrate 101, an active region is defined by device isolation layers. Source/drain regions 128 that include impurities are disposed in a portion of the active region.

The circuit devices 120 includes a transistor. Each of the circuit devices 120 includes a circuit gate dielectric layer 122, a circuit gate electrode 124, and a source/drain region 128. The source/drain regions 128 include impurities and are disposed in the first substrate 101 on both sides of the circuit gate electrode 124. Spacer layers 126 are disposed on both sides of the circuit gate electrode 124. The circuit gate dielectric layer 122 includes at least one of silicon oxide, silicon nitride, or a high-k material. The circuit gate electrode 124 includes at least one of doped silicon, titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). For example, the circuit gate electrode 124 includes a doped polycrystalline silicon layer. According to an embodiment, the circuit gate electrode 124 includes two or more multiple layers.

The lower interconnection structure 130 is electrically connected to the circuit gate electrodes 124 and the source/drain regions 128 of the circuit devices 120. The lower interconnection structure 130 includes lower contact plugs 135 and lower interconnection lines 137 in which at least one region has a line shape. A portion of lower contact plugs 135 are connected to the source/drain regions 128 and the other portion of lower contact plugs 135 are connected to the gate electrodes 124. The lower contact plugs 135 electrically connect the lower interconnection lines 137 disposed on different levels from the upper surface of the first substrate 101 to each other. The lower interconnection structure 130 includes a conductive material, such as at least one of tungsten (W), copper (Cu), or aluminum (Al), etc., and each component further includes a diffusion barrier that includes at least one of titanium (Ti), titanium nitride (TiN), tantalum (Ta), tantalum nitride (TaN), or tungsten nitride (WN). In embodiments, the number of layers and the arrangement form of the lower contact plugs 135 and the lower interconnection lines 137 in the lower interconnection structure 130 can vary.

The lower bonding structure 180 is connected to the lower interconnection structure 130. The lower bonding structure 180 includes a lower bonding via 182, a lower bonding pad 184, and a lower bonding insulating layer 186. The lower bonding via 182 is connected to the lower interconnection structure 130. The lower bonding pad 184 is connected to the lower bonding via 182. The lower bonding via 182 and the lower bonding pad 184 include conductive materials, such as at least one of tungsten (W), copper (Cu), or aluminum (Al), etc., and each component further includes a diffusion barrier. The lower bonding insulating layer 186 also functions as a diffusion barrier of the lower bonding pad 184 and includes at least one of SiCN, SiO, SIN, SiOC, SiON or SiOCN. The lower bonding insulating layer 186 has a thickness that is less than a thickness of the lower bonding pad 184, but an embodiment thereof is not necessarily limited thereto. The lower bonding structure 180 is in direct contact with and bonded or connected to the upper bonding structure 280 by hybrid bonding. For example, the lower bonding pad 184 is in direct contact with and coupled to the upper bonding pad 284 by copper-to-copper bonding (copper (Cu)-copper (Cu) bonding), and the lower bonding insulating layer 186 is in direct contact with and coupled to the upper bonding insulating layer 286 by dielectric-to-dielectric bonding. The lower bonding structure 180, together with the upper bonding structure 280, provide an electrical connection path between the peripheral circuit region PERI and the memory cell region CELL.

The lower capping layer 190 is disposed on the first substrate 101 and covers the circuit devices 120 and the lower interconnection structure 130. The lower capping layer 190 may include a plurality of insulating layers. The lower capping layer 190 includes an insulating material, such as at least one of silicon oxide, silicon nitride, silicon oxynitride, or silicon oxycarbide.

The memory cell region CELL includes a first material layer 203 that includes a first region R1, a second material layer 202 on the lower surface of the first material layer 203, a buffer layer 201 on the lower surface of the second material layer 202, gate electrodes 230 stacked on the lower surface of the buffer layer 201 and that include the first region R1 and the second region R2, interlayer insulating layers 220 alternately stacked with the gate electrodes 230, channel structures CH that penetrate through the gate electrodes 230, isolation regions MS that extend in one direction through the gate electrodes 230, and first insulating regions GS that penetrate through a portion of the gate electrodes 230. The memory cell region CELL includes a horizontal insulating layer 219A parallel with and adjacent to the first and second material layers 203 and 202 in the second region R2, a passivation layer 219B disposed on the first material layer 203, second insulating regions SS that 53apenetrate through a portion of the gate electrodes 230, and an upper capping layer 290 that covers the gate electrodes 230. The interlayer insulating layers 220 alternately stacked with the gate electrodes 230 form a stack structure ST.

The memory cell region CELL includes gate contact plugs 252 that are electrically connected with the peripheral circuit region PERI, an upper interconnection structure 270 below the stack structure ST, and an upper bonding structure 280 connected to the upper interconnection structure 270.

The memory cell region CELL furthers include dummy vertical structures DVH, gate contact plugs 252, and a substrate contact via 267 on the body interconnection 254 in the second region R2.

As illustrated in FIG. 3A, in the first region R1, the gate electrodes 230 are stacked and spaced apart from each other in a vertical direction, for example, the Z-direction, and the channel structures CH are disposed. As illustrated in FIG. 3A, in the second region R2, the gate electrodes 230 have different lengths in the X-direction such that contact pads that electrically connect the memory cells to the peripheral circuit region PERI are provided. Also, in the second region R2, a source interconnection 253 and a body interconnection 254 may be disposed. The second region R2 further includes a region that extends from a side end of the gate electrodes 230 to an edge of the semiconductor device 100. For example, the second region R2 further includes a region in which the conductive pad 300 is disposed. The second region R2 extends in at least in one direction, for example, from at least one end of the first region R1 in the X-direction.

The first region R1 and second region R2 include regions both below and above the passivation layer 219B, including the passivation layer 219B.

Referring to FIG. 3C, each of the channel structures CH includes a filling insulating layer 247, a channel layer 240 on a side surface and an upper surface of the filling insulating layer 247, and a data storage structure 245 between the outer side surface of the channel layer 240 and the stack structure ST. The data storage structure 245 includes a tunneling layer 241, a data storage layer 242, and a blocking layer 243 that are sequentially stacked from the channel layer 240. The tunneling layer 241 tunnels electric charges into the charge storage layer 242 and includes, for example, at least one of silicon oxide (SiO₂), silicon nitride (Si₃N₄), silicon oxynitride (SiON), or a combination thereof. The data storage layer 242 is a material layer that can store data. For example, the data storage layer 242 may be configured as an electric charge trap layer or a floating gate conductive layer. The blocking layer 243 includes at least one of silicon oxide (SiO₂), silicon nitride (Si₃N₄), silicon oxynitride (SiON), a high-K material, or a combination thereof.

As illustrated in the enlarged view in FIG. 3C, each of the channel structures CH includes a first portion in the stack structure ST and a second portion that upwardly protrudes above the stack structure ST. The channel layer 240 is disposed entirely in the first and second portions of the channel structure CH, and extends up to the upper end of the second portion. The channel layer 240 includes a protrusion 240a that upwardly protrudes above the stack structure in the second portion and a non-protruding portion 240b disposed in the stack structure ST and the first portion of the channel structure CH.

The first material layer 203 has a first conductivity. For example, the first material layer 203 includes a first semiconductor material that has a P-type conductivity. For example, the first material layer 203 includes a doped semiconductor material, such as one of a group IV semiconductor, a group III-V compound semiconductor, or a group II-VI compound semiconductor. For example, a group IV semiconductor includes one of silicon, germanium, or silicon-germanium. For example, the first material layer 203 includes a silicon layer, such as a silicon layer that has a P-type conductivity. For example, the first material layer 203 is a crystalline semiconductor layer such as one of a single crystalline silicon layer, a polycrystalline silicon layer, or an epitaxial layer. The first material layer 203 functions as a body selection line (BSL) that provides an erase voltage during an erase operation in first region R1. As illustrated in the enlarged view in FIG. 3C, the first material layer 203 overlaps the channel structures CH in the Z-direction, and at least a portion of channel structures CH, such as an end and a portion of a side surface adjacent to the end of channel structures CH, is electrically connected through the buffer layer 201.

The second material layer 202 is disposed between a lower surface of the first material layer 203 and the stack structure ST in the first region R1. The second material layer 202 has a second conductivity that differs from the first conductivity. For example, the second material layer 202 includes a second semiconductor material that has an N-type conductivity. For example, the second material layer 202 includes a doped semiconductor material, such as one of a group IV semiconductor, a group III-V compound semiconductor, or a group II-VI compound semiconductor. For example, a group IV semiconductor includes one of silicon (Si), germanium (Ge), or silicon-germanium (SiGe). The second material layer 202 functions as a common source line (CSL) of the semiconductor device 100. For example, the second material layer 202 includes a silicon layer, such as a silicon layer that has N-type conductivity. For example, the second material layer 202 is provided as a crystalline semiconductor layer or an epitaxial layer, such as a single crystal silicon layer or a polycrystalline silicon layer doped with second conductivity-type impurities that differ from that of the first material layer 203. As illustrated in the enlarged view in FIG. 3C, the second material layer 202 includes openings 2020 through which the channel structures CH penetrate, and the openings 2020 surround the side surface of the second portions of the channel structures CH, that is, the side surface of the protrusion 240A of the channel layer 240. Accordingly, the second material layer 202 does not overlap the channel structure CH in the Z-direction. The second material layer 202 surrounds one region of the protrusion 240A of the channel structure CH, such as a portion of the side surface, and is electrically connected to the channel layer 240 through the buffer layer 201. The buffer layer 201 is disposed below the second material layer 202.

The buffer layer 201 includes a semiconductor material, such as one of a group IV semiconductor, a group III-V compound semiconductor, or a group II-VI compound semiconductor. For example, a group IV semiconductor includes one of silicon (Si), germanium (Ge), or silicon-germanium (SiGe). According to an embodiment, the buffer layer 201 conformally covers the channel structures CH, but an embodiment thereof is not necessarily limited thereto.

The buffer layer 201 includes a silicon layer. For example, the buffer layer 201 is one of an undoped single crystalline silicon layer, an undoped crystalline semiconductor layer such as an undoped polycrystalline silicon layer, or an undoped epitaxial layer.

The buffer layer 201 is interposed between the second material layer 202 and the stack structure ST, between the second material layer 202 and the second portions of the channel structures CH, and between the first material layer 203 and the second portions of the channel structures CH. The buffer layer 201 is in contact with the second material layer 202, and is in contact with the first material layer 203 in a portion of regions and is selectively electrically connected with the channel layer 240 of the channel structure CH and the first material layer 203 or the second material layer 202.

The first material layer 203, the second material layer 202 and the buffer layer 201 are sequentially stacked in the first region RI and in the boundary regions between the first region R and the second region R2. For example, the first material layer 203, the second material layer 202 and the buffer layer 201 do not extend through the entire second region R2, and extend only to the first region R1 and a portion of the second region R2 adjacent to the first region R1 in the X-direction. For example, the first material layer 203, the second material layer 202 and the buffer layer 201 extend to the first region R1 and a boundary region of the second region R2, where a source interconnection 253 and the body interconnection 254 electrically connected to the common source line and the body selection line.

In the first region R1 and the boundary region of the second region R2, the second material layer 202 extends further from the first material layer 203 toward the second region R2. In the extended region of the second material layer 202, the second material layer 202 is connected to the upper source interconnection 253, and the source interconnection 253 does not overlap the first material layer 203 in the Z-direction.

The memory cell region CELL further includes an upper conductive layer 204 in contact with the first material layer 203 and disposed on the first material layer 203. The upper conductive layer 204 is a conductive layer in contact with the first material layer 203. The upper conductive layer 204 includes at least one of a metal-semiconductor compound, a metal-nitride, or a metal, such as tungsten (W), copper (Cu), or aluminum (Al).

The upper conductive layer 204 is vertically aligned with the first material layer 203. The memory cell region CELL further includes a body contact via 268 on the upper conductive layer 204 and the body interconnection 254 on the body contact via 268.

The first material layer 203 and the second material layer 202 do not extend to the second region R2, but the buffer layer 201 does extend to the second region R2, but an embodiment thereof is not limited.

The first material layer 203, the second material layer 202 and the buffer layer 201 include a semiconductor material and, for example, include crystalline silicon.

The first material layer 203 is doped with first conductivity-type impurities, the second material layer 202 is doped with second conductivity-type impurities that differs from the first conductivity, and a portion of the buffer layer 201 becomes conductive as first and second conductivity-type impurities diffuse downward, and the remaining portion of the buffer layer 201 is an undoped semiconductor layer.

For example, the first material layer 203 is a polycrystalline silicon layer doped with P-type impurities, the second material layer 202 is a polycrystalline silicon layer doped with N-type impurities, and the buffer layer 201 is an undoped polycrystalline silicon layer.

The horizontal insulating layer 219a is disposed parallel to the first material layer 203 and the second material layer 202 in at least a portion of the second region R2. The horizontal insulating layer 219a is a multilayer structure in the second region R2. For example, a portion of the multilayer structure is undoped crystalline silicon that is simultaneously formed with the buffer layer 201, and includes at least one of silicon oxide, silicon nitride, silicon carbide, or silicon oxynitride. For example, the horizontal insulating layer 219a includes a lower horizontal insulating layer and an upper horizontal insulating layer that include different insulating materials.

The gate electrodes 230 are vertically stacked and spaced apart from each other on the lower surface of the horizontal insulating layer 219a and the buffer layer 201 and form the stack structure ST along with the interlayer insulating layers 220. The stack structure ST includes vertically stacked lower and upper stack structures. However, in embodiments, the stack structure includes a single stack structure.

The gate electrodes 230 include at least one lower gate electrode 230L that forms the gate of the ground selection transistor, memory gate electrodes 230M that form the plurality of memory cells, and upper gate electrodes 230U that forms the gates of the string selection transistors. In the terms “the lower gate electrode 230L and the upper gate electrodes 230U”, “lower” and “upper” refer to a direction during a manufacturing process. The number of memory gate electrodes 230M that form the memory cells is determined by a capacity of the semiconductor device 100. In embodiments, the number of the upper gate electrodes 230U and the number of the lower gate electrodes 230L is one to two or more, and have a structure the same as or different from the memory gate electrodes 230M. In an embodiment, erase gate electrodes are further disposed below the upper gate electrodes 230U, but in an embodiment in which a bulk erase operation is performed, an erase operation is performed without the erase gate electrodes. In addition, a portion of the gate electrodes 230, such as the memory gate electrodes 230M adjacent to the upper or lower gate electrodes 230U and 230L, may be dummy gate electrodes, but an embodiment thereof is not necessarily limited thereto.

The gate electrodes 230 are vertically stacked and spaced apart from each other on the lower surface of the horizontal insulating layer 219A and the buffer layer 201, extend with different lengths in at least one direction and form a step structure with a staircase shape. The gate electrodes 230 form a step structure in the X-direction as illustrated in FIG. 3A, and form a step structure in the Y-direction as well. Due to the step structure, the ends of the gate electrodes 230 are exposed. The gate electrodes 230 are connected to gate contact plugs 252 in the second region R2.

The gate electrodes 230 include a metal, such as tungsten (W). In embodiments, the gate electrodes 230 include polycrystalline silicon or a metal silicide. In embodiments, the gate electrodes 230 further include a diffusion barrier. For example, the diffusion barrier includes at least one of tungsten nitride (wN), tantalum nitride (TaN), titanium nitride (TiN), or a combination thereof.

At least a portion of the gate electrodes 230 is isolated by isolation regions MS in the Y-direction. The isolation regions MS penetrate through the gate electrodes 230 and extend in the Z-direction in the memory cell array region MCA and connection region CA. The isolation regions MS extend in the X-direction and isolate the gate electrodes 230 from each other in the Y-direction. The isolation regions MS are spaced apart from each other in the Y-direction and are parallel to each other. The gate electrodes 230 between a pair of adjacent isolation regions MS form a memory block, but the range of the memory block is not necessarily limited thereto. A width of the isolation region MS decreases toward the horizontal insulating layer 219A and the buffer layer 201, but an embodiment thereof is not necessarily limited thereto. An isolation insulating layer 264 is disposed in the isolation regions MS. In embodiments, in the isolation regions MS, a conductive layer is further disposed in the isolation insulating layer 264. The isolation insulating layer 264 includes an insulating material such as silicon oxide or silicon nitride, such as one of silicon oxide, silicon nitride, or silicon oxynitride. In embodiments, the arrangement order and the number of the isolation regions MS are not necessarily limited to the illustrated examples in FIG. 2A.

The interlayer insulating layers 220 are disposed between the gate electrodes 230. Similar to the gate electrodes 230, the interlayer insulating layers 220 are spaced apart from each other in a direction perpendicular to the lower portion of the horizontal insulating layer 219A and the buffer layer 201, such as a Z-direction, and extend in the X-direction. The interlayer insulating layers 220 include an insulating material such as silicon oxide or silicon nitride.

The channel structures CH are spaced apart from each other in rows and columns below the lower surface of the first and second material layers 203 and 202 in the first region R1. The channel structures CH are disposed in a zigzag pattern in one direction on the X-Y plane, such as the X-direction. The channel structures CH penetrate through the gate electrodes 230, extend in a vertical direction perpendicular to the lower surface of the first material layer 203, such as the Z-direction, have a pillar shape, and have an inclined side surface and a width that decreases toward the first material layer 203.

Each of the channel structures CH includes lower and upper channel structures that respectively penetrate through a lower gate stack group and an upper gate stack group of the gate electrodes 230 are connected to each other, and may have a bent portion due to a difference or change in width in the connection region.

In an embodiment, protruding lengths of the second portions of the channel structures CH and the protrusions 240A of channel layer 240 might not be the same, but an embodiment thereof is not limited thereto. The channel layer 240 has an annular side surface that surrounds the internal filling insulating layer 247, but in other embodiments, the channel layer 240 has a pillar shape, such as a cylindrical shape or a prism shape, without a filling insulating layer 247. The protrusion 240A of the channel layer 240 is in contact with the second material layer 202 and the first material layer 203 with the buffer layer 201 interposed therebetween. The protrusion 240A of the channel layer 240 is connected to the buffer layer 201. The channel layer 240 includes a semiconductor material such as one of a polycrystalline silicon or a single crystal silicon, and the semiconductor material may be an undoped material or a material including P-type or N-type impurities. According to an embodiment, at least a portion of the side surface of the protrusion 240A of the channel layer 240 is spaced apart from the second material layer 202 with the buffer layer 201 therebetween, and an upper end portion and at least a portion of the side surface adjacent to the upper end portion are spaced apart from the first material layer 203 with the buffer layer 201 therebetween. Accordingly, the protrusion 240A of the channel layer 240 overlaps the first material layer 203 in the Z-direction, but does not overlap the second material layer 202 in the Z-direction.

Accordingly, when an appropriate voltage level is applied to each material layer 203 and 202, the first material layer 203 or the second material layer 202 electrically connects to the channel layer 240 through the buffer layer 201.

Accordingly, the height of the second portion of the channel structure CH, that is, the height of protrusion 240A, is greater than the sum of the thicknesses of the buffer layer 201 and the second material layer 202, and the height of protrusion 240A of the channel layer 240 is defined as the length from the upper surface of the data storage structure 245 to an upper end of the channel layer 240. Accordingly, the upper surfaces of the second portions of the channel structures CH are located at a higher level than the upper surface of the second material layer 202, and the protrusion 240A protrudes above the upper surface of the second material layer 202 by a predetermined height h1. For example, the protrusion 240A has a slope with the non-protruding portion 240B to maintain the annular shape, as illustrated in FIG. 3C.

For example, in the protrusion 240A, as the channel layer 240 is in contact with the first material layer 203 and the second material layer 202 and the buffer layer 201, depending on the voltage applied to the first material layer 203 or the second material layer 202, the channel layer 240 is selectively electrically connected to one of the specific material layers 203 and 202 and a current can flow therethrough.

The second material layer 202 is a common source. To perform an erase operation in which electrons trapped in the data storage layer 242 in the data storage structure 245 escape into the channel layer 240, an erase voltage is applied to the first material layer 203, holes flow from the first material layer 203 into the channel layer 240 through the buffer layer 201, and the erase operation in which electrons trapped in the data storage layer 242 may escape into the channel layer 240 is performed.

For example, the second material layer 202 doped with N-type impurities and the first material layer 203 doped with P-type impurities are simultaneously connected to the protrusion 240A of the channel layer 240, and can be selectively electrically connected depending on the applied voltage, such that the required operation can be performed.

For example, since a bulk erase operation can be performed, an erase operation can be performed at a faster speed than performing the erase operation of the channel layer 240 using a general erase transistor GIDL TR using gate-drain leakage current, and by operating without an erase transistor, a relatively fast operation speed may be secured.

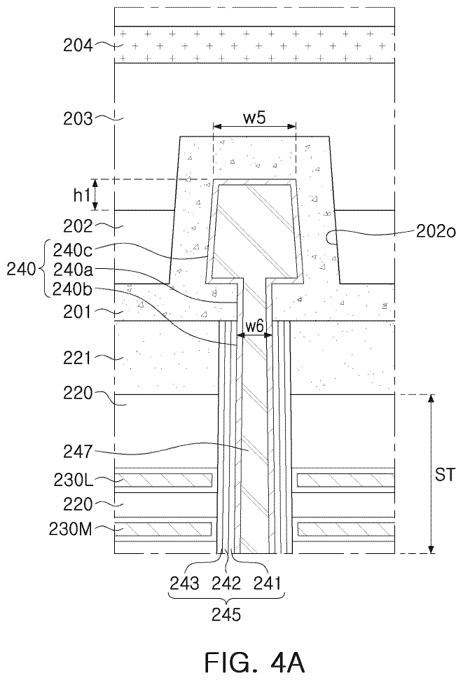

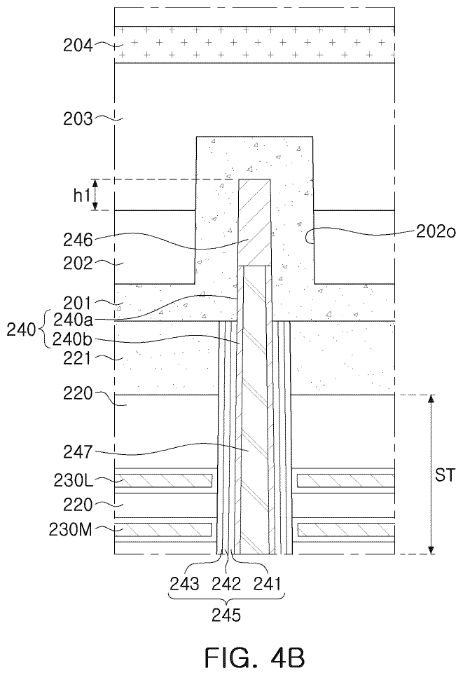

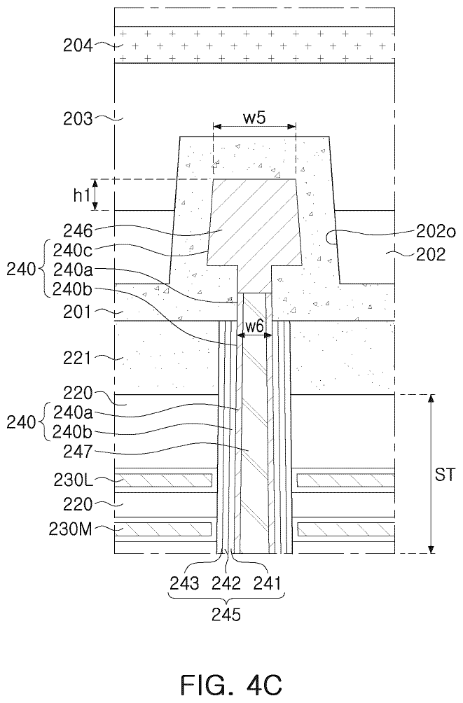

In an embodiment, the channel structure CH further includes a head 240C that has an expanded width on one end in the second region as illustrated in FIG. 4A.

In an embodiment illustrated in FIG. 4A, a head 240C of the channel structure CH has a width w5 that is greater than a width w6 of the first portion of the channel structure CH. The head 240C of the channel structure CH is a stopper that maintains the depth of the channel hole uniformly during the manufacturing process, but an embodiment thereof is not necessarily limited thereto.

The head 240C may have different widths w5 in Z-direction. For example, the head 240C has a width w5 that decreases upwardly, but an embodiment thereof is not necessarily limited thereto, and in some embodiments, the upper and lower widths of the head 240C are the same. For example, the width w5 on the smallest head 240C is greater than the width w6 of the first portion of the channel structure CH.

For example, the width w5 of head 240C is about ½ to ⅗ of the spacing distance between neighboring channel structures CH.

For example, when the spacing distance between neighboring channel structures CH is about 140 nm to 150 nm, the width w5 of head 240C is about 70 nm to 85 nm. The width w6 of the first portion of the channel structure CH is about 59 nm to 61 nm, or about 60 nm.

Even when the head 240C is formed, the stack structure of the second region of the channel structures CH is the same as in FIG. 3C, and the height of the protrusion 240A is greater than the sum of the thicknesses of the buffer layer 201 and the second material layer 202. Accordingly, the head 240C protrudes above the upper surface of the second material layer 202 by a predetermined height h1. The shape of the head 240C is determined by the filling insulating layer 247.

For example, when the head 240C of the protrusion 240A is formed, the contact area between the first material layer 203 and the channel layer 240 is expanded by the surface area of the head 240C, thereby increasing the amount of inflow of holes during a bulk erase operation.

As illustrated in FIG. 4B, in an embodiment, in a portion of the channel protrusion 240A, such as a region close to the upper end thereof, the filling insulating layer 247 is not formed, and a pad pattern 246 that includes a polycrystalline semiconductor layer that is the same as the channel layer 240 is formed. Accordingly, each of the channel structures CH further includes a pad pattern 246 connected to the channel layer 240. The pad pattern 246 includes an undoped semiconductor, such as undoped silicon.

The height of the protrusion 240A is greater than the sum of the thicknesses of the buffer layer 201 and the second material layer 202. Accordingly, the upper surface of the protrusion 240A protrudes above the upper surface of the second material layer 202 by a predetermined height h1 and has a higher level.

In another embodiment, as illustrated in FIG. 4C, the channel structure CH further includes a head 240C having an extended width w5 on an end of the second portion. The head 240C has the same shape as that shown in FIG. 4A. The height of the protrusion 240A is greater than the sum of the thicknesses of the buffer layer 201 and the second material layer 202. Accordingly, the head 240C of the protrusion 240A protrudes above the upper surface of the second material layer 202 by a predetermined height h1.

The region of the protrusion 240A that extends from the head 240C of the protrusion 240A has a pad pattern 246 as illustrated in FIG. 4B in which the filling insulating layer 247 is not formed. Accordingly, the head 240C, which is a pad pattern, includes an undoped semiconductor, such as undoped silicon.

In the channel structures CH, channel pads 249 are disposed in a lower portion of the channel layer 240. The channel pads 249 cover the lower surface of the filling insulating layer 247 and are electrically connected to the channel layer 240. The channel pads 249 include, for example, doped polycrystalline silicon.

The data storage structure 245 is disposed between the gate electrodes 230 and the channel layer 240. The data storage structure 245 includes the tunneling layer 241, the charge storage layer 242, and the blocking layer 243 that are sequentially stacked from the channel layer 240. In embodiments, at least a portion of the data storage structure 245 forms a first channel dielectric layer that extends horizontally along the gate electrodes 230.

The data storage structure 245 is removed from the upper portion of the stack structure such that the protrusion 240A of the channel layer 240 in the second portion is exposed. Accordingly, the upper surface of the data storage structure 245 is in contact with the buffer layer 201, and the side surface of the data storage structure 245 in the first portion surrounds the non-protruding portion 240B of the channel layer 240.

The channel layer 240, the gate dielectric layer 245, and the filling insulating layer 247 are connected to each other between the upper channel structure and the lower channel structure. An interlayer insulating layer 220 that has a relatively great thickness is further disposed between the upper channel structure and the lower channel structure. However, the form of the interlayer insulating layers 220 varies in other embodiments.

The dummy vertical structures DVH are disposed in the second region R2 and have a structure that is the same as or similar to the channel structures CH, but do not perform a practical function in the semiconductor device 100. The dummy vertical structures DVH are disposed regularly in columns and rows in the second region R2. The dummy vertical structures DVH has a diameter that is greater than a maximum diameter of the gate contact plugs 252. The shape, the number and/or the spacing of dummy vertical structures DVH can vary. The channel structures CH and the dummy vertical structures DVH may have a substantially circular shape in a plan view, but an embodiment thereof is not necessarily limited thereto, and in some embodiments, the channel structures CH and the dummy vertical structures DVH have an oval shape. The dummy vertical structures DVH prevent deformation such as warpage of the stack structure ST.

Each of the gate contact plugs 252 has a cylindrical shape or a truncated cone shape, and a width thereof decreases upwardly. The gate contact plugs 252 penetrate through a portion of the cell region insulating layer 290. A plurality of the gate contact plugs 252 are disposed and are spaced apart from each other.

The gate contact plugs 252 are disposed in the second region R2 and extend in a vertical direction, such as the Z-direction. The gate contact plugs 252 are connected to ends or contact pads according to the staircase shape of the gate electrodes 230. The gate contact plugs 252 are connected to the upper interconnection structure 270 in a lower portion.

The second semiconductor structure S2 further includes conductive patterns 253 and 254 spaced apart from each other on the first material layer 203 and in the passivation layer 219b in the boundary region between first region R1 and second region R2, and a plurality of vias 267, 268 in contact with the conductive patterns 253 and 254. The conductive patterns 253 and 254 include source interconnections 253 that overlap the second material layer 202 and body interconnections 254 that overlap the first material layer 203.

The plurality of vias include source contact vias 267 disposed between the source interconnections 253 and the second material layer 202 and body contact vias 268 disposed between the body interconnection 254 and upper conductive layer 204.

The plurality of source contact vias 267 penetrate through the passivation layer 219b and the horizontal insulating layer 219a and are in contact with the second material layer 202 and the source interconnection 253.

The plurality of body contact vias 268 penetrate through the passivation layer 219b and are in contact with the upper conductive layer 204 and the body interconnection 254.

As illustrated in FIG. 2C, the body interconnection 254 and the source interconnection 253 are disposed on the dummy channel structure DVH. The components are formed on the dummy channel structure DVH of the second region R2, and the first material layer 203, the second material layer 202, and the buffer layer 201 extend into the second region R2. In the example in FIG. 2C, the regions of the body interconnection 254 and the source interconnection 253 does not extend further into the second region R2 in the X-direction.

The isolation regions MS penetrate through the gate electrodes 230 and extend in the X-direction. The isolation regions MS extend parallel to each other. The isolation regions MS penetrate through the entirety of the gate electrodes 230 stacked on the buffer layer 201 and the horizontal insulating layer 219a, and may be connected to the buffer layer 201 and the horizontal insulating layer 219a. Each of the isolation regions MS is an integrated layer that extends in the X-direction. A sub-isolation region that extends intermittently between the isolation regions may be formed, but an embodiment thereof is not necessarily limited thereto.

As illustrated in FIG. 3B, in an embodiment, the isolation insulating layer 264 is disposed in the isolation regions MS. The isolation insulating layer 264 has a shape whose width decreases toward the buffer layer 201 and the horizontal insulating layer 219A, but an embodiment thereof is not necessarily limited thereto. In some embodiments, a conductive layer is further disposed in the isolation insulating layer 264. For example, the conductive layer functions as a contact plug connected to the common source line and the body selection line of the semiconductor device 100.

The first insulating regions GS extend from the upper surface of the first material layer 203, and penetrate through the first and second material layer 202, the buffer layer 201 or the horizontal insulating layer 219a, the lower gate electrodes 230L, and a portion of the interlayer insulating layers 220.

At least one first insulating region GS is disposed higher than a level of the intermediate memory gate electrodes 230M and penetrates through the lower gate electrodes 230L in the vertical direction. As illustrated in FIG. 2A, the first insulating regions GS extends in the X-direction through the first region R1 and the second region R2 in a plan view. The first insulating regions GS have a wavy shape that extends in the X-direction, for example, a shape that oscillates in the X-Y plane and is continuously bent, such as a wave pattern shape.

Due to this shape, the lower gate electrodes 230L are isolated or divided into disposed in a row in the X-direction.

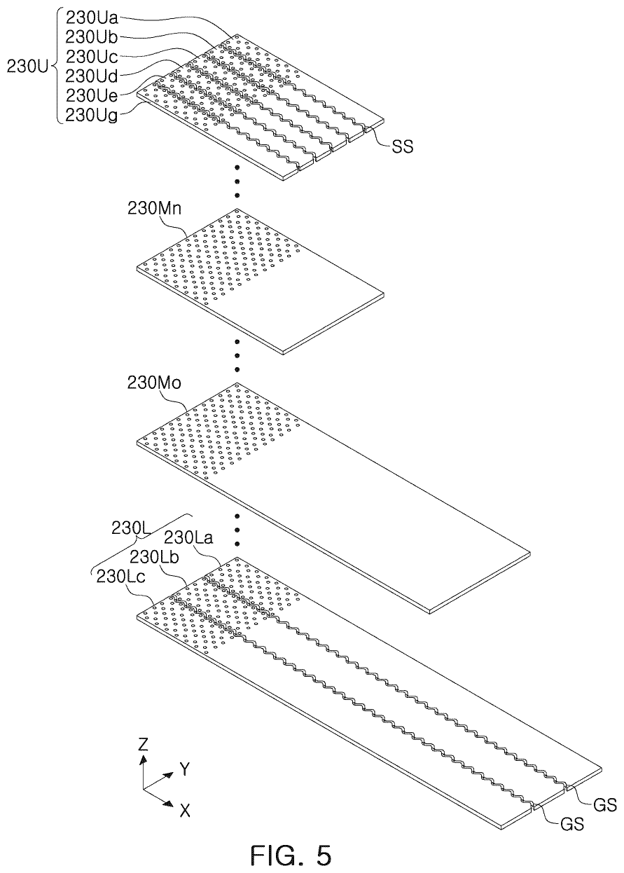

The above embodiment will be described in greater detail with reference to FIG. 5 below.

As illustrated in FIG. 2B, in an embodiment, the first insulating regions GS form a plurality of regions between two isolation regions MS spaced apart from each other in the Y-direction.

The first insulating regions GS form two to three regions between two adjacent isolation regions MS, and the ground selection gate electrode, which is the lower gate electrode 230L, may be divided depending on the vertical extension of the first insulating regions GS.

Each first insulating region GS extends in the X-direction in a wavy shape, and an extension direction thereof has a same length in the X-direction as the isolation region MS.

The wavy shape of the first insulating region GS is disposed between the plurality of channel structures CH in the plan view.

As illustrated in FIG. 2B, when the plurality of channel structures CH are disposed a zigzag pattern in the X-Y plane, the first insulating region GS has a wavy shape to continuously pass between the channel structures CH arranged in a zigzag pattern.

Each first insulating region GS has the same width w1 in the X-Y plane, but an embodiment thereof is not necessarily limited thereto, and as the width w1 decreases toward the channel structure CH, the first insulating region GS is spaced apart from the channel structure CH by a predetermined distance d1 or more.

Accordingly, the first insulating region GS has a smaller structure in a mountain n1 and a valley n2, but an embodiment thereof is not necessarily limited thereto.

In addition, a width w4 of a two-row channel structure CH that extends in the X-direction is greater than a width w3 of the path of the first insulating region GS. Accordingly, the path of the first insulating region GS is bent in the region between the two rows of channel structures CH, such that the first insulating region GS does not contact the channel structures CH.

In addition, a distance d3 between two channel structures CH between which the first insulating region GS passes, that is, the distance d3 between the central points O1 and O3 of the center of the channel structures CH and the distance d2 between two channel structures CH between which the first insulating region GS does not pass is the same as the distance d3.

Accordingly, even when the first insulating region GS extends between the channel structures CH, the spacing distances d2 and d3 between the channel structures CH is not widened and the arrangement between the channel structures CH is not changed. In addition, since the first insulating region GS extends between the isolation regions MS, an additional isolation region MS is not disposed between the isolation regions MS. Accordingly, a density of the channel structure CH is increased, and no dummy channel structure DVH are formed in the first insulating regions GS. Accordingly, cell capacity in the same area is increased, such that memory capacity can be secured.

The first insulating layer 206 is disposed in the first insulating region GS. The first insulating layer 206 includes an insulating material, such as one of silicon oxide, silicon nitride, or silicon oxynitride.

As illustrated in FIG. 3B, the first insulating region GS has inclined side surfaces such that a width thereof decreases toward the first substrate structure S1. The first insulating region GS has side surfaces inclined or tapered in an opposite direction from the channel structures CH, the isolation regions MS, the upper interconnection structure 270, and the upper bonding structure 280. The first insulating region GS is wider in an upper portion than in a lower portion.

The first insulating region GS completely penetrates through the lower gate electrodes 230L from the first material layer 203, and a lower end thereof is disposed in the interlayer insulating layer 220 below the lower gate electrodes 230L. For example, with respect to the memory gate electrodes 230M, when the upper gate electrodes 230 are referred to as lower gate electrodes 230L and the lower gate electrodes 230 are referred to as upper gate electrodes 230U, the first insulating region GS penetrates at least a portion of the lower gate electrodes 230L.

The lower gate electrode 230L penetrated by the first insulating region GS are exposed by the first insulating region GS and are in direct contact with the first insulating layer 206. In addition, the side surfaces of gate dielectric layers on the upper and lower surfaces of the lower gate electrode 230L are exposed through the first insulating region GS and are in direct contact with the first insulating layer 206. That is, in the gate electrodes 230, the side surface that opposes the channel structure CH is covered with gate dielectric layers as illustrated in FIG. 3C, and the side surface that opposes the first insulating region GS is not covered with gate dielectric layers as illustrated in FIG. 3B. This is because the first insulating region GS is formed after the gate dielectric layers and the gate electrodes 230 are formed. In addition, the gate electrodes 230 below the first insulating region GS including the memory gate electrodes 230M and have flat upper and lower surfaces and extend to a region below the first insulating region GS.

In an embodiment, the first insulating region GS is formed from the upper surface of the first material layer 203 after the first and second substrate structures S1 and S2 are bonded to each other. Accordingly, since the shape of the gate electrodes 230 is not affected by the first insulating region GS, the gate electrodes 230 have flat upper and lower surfaces below the first insulating region GS. Accordingly, different from an example in which the first insulating region GS is formed before the gate electrodes 230 are formed, a seagull-shaped recess is prevented from forming in the gate electrodes 230, such that defects of the gate electrodes 230 due to the recess, such as short circuit defects and leakage current defects, can be prevented.

The second insulating regions SS extend in the X-direction between two isolation regions MS spaced apart from each other in the Y-direction in the first region R1, as illustrated in FIG. 2A. The second insulating regions SS have a wavy shape that extends in the X-direction, similar to the first insulating regions GS on the X-Y plane.

The second insulating regions SS penetrate through a portion of the gate electrodes 230 that includes the lowermost upper gate electrode 230U. The second insulating regions SS isolate the upper gate electrodes 230U from each other in the Y-direction, as illustrated in FIG. 3B. However, the number of gate electrodes 230 isolated by the second insulating regions SS can vary in embodiments. The upper gate electrodes 230U isolated by the second insulating regions SS form different string selection lines. In the second insulating regions SS, the second insulating layer 213 is disposed. The second insulating layer 213 includes an insulating material, such as one of silicon oxide, silicon nitride, or silicon oxynitride.

As illustrated in FIG. 2B, when the lower gate electrode 230L is divided into n number of portions by the first insulating regions GS, the upper gate electrode 230U are divided into 2n number of portions by the second insulating regions SS.

The plurality of second insulating regions SS include at least one first-second insulating region SS that overlaps a first insulating region GS in the Z-direction, and a second-second insulating region SS that does not overlap a first insulating region GS in the Z-direction. When two first insulating regions GS are formed between two isolated isolation regions MS, the lower gate electrodes 230L are divided into three portions, five second insulating regions SS are formed, and the 230U upper gate electrodes are divided into six portions. The width of the second insulating region SS is less than the width of the first insulating region GS, but an embodiment thereof is not necessarily limited thereto.

A extension length in the X-direction of the second insulating region SS is shorter than that of the first insulating region GS in the X-direction.

The upper capping layer 290 covers the gate electrodes 230 disposed on the lower surface of the buffer layer 201 and the horizontal insulating layer 219A. The upper capping layer 290 is formed of an insulating material and may include a plurality of insulating layers.

The passivation layer 219b is disposed on the upper surface of the first material layer 203. The passivation layer 219b protects the semiconductor device 100. In an embodiment, the passivation layer 219b has openings in some regions that define a pad region connected to an external device. The passivation layer 219b includes at least one of silicon oxide, silicon nitride, or silicon carbide.

An etch stop layer 221 is further disposed above the uppermost interlayer insulating layer 220. The etch stop layer 221 is formed such that only the base substrate is removed in an etching process due to etch selectivity with respect to a sacrificial base substrate. To this end, the etch stop layer 221 includes a semiconductor material, such as one of a group IV semiconductor, a group III-V compound semiconductor, or a group II-VI compound semiconductor. For example, a group IV semiconductor includes one of silicon (Si), germanium (Ge), or silicon-germanium (SiGe). According to an embodiment, the etch stop layer 221 is as an undoped crystalline semiconductor layer, and, for example, is formed of undoped polycrystalline silicon, but an embodiment thereof is not necessarily limited thereto.

When the etch stop layer 221 is disposed on the uppermost interlayer insulating layer 220, the etch stop layer 221 is disposed throughout the first region RI and the second region R1.

The upper interconnection structure 270 electrically connects the upper conductive layer 204 of the gate electrodes 230, the channel structures CH, the second material layer 202 and the first material layer 203 to the circuit devices 120. The upper interconnection structure 270 includes a channel contact plug 271, a gate contact stud 272, an upper contact plug 275, and an upper interconnection line 277. The channel contact plug 271 is connected to the channel pad 249 of the channel structure CH. The channel contact plug 271 is electrically connected to the channel layer 240 through the channel pad 249 of the channel structures CH in the memory cell array region MCA. The upper contact plugs 275 are connected to the channel contact plug 271 and the gate contact stud 272. The gate contact stud 272 is connected to the gate contact plug 252. The upper interconnection line 277 is connected to the upper contact plug 275. The upper interconnection structure 270 includes a conductive material, such as one of tungsten (W), copper (Cu), or aluminum (Al), etc., and each component further includes a diffusion barrier that includes at least one of titanium (Ti), titanium nitride (TiN), tantalum (Ta), tantalum nitride (TaN), or tungsten nitride (WN). In embodiments, the number of the upper contact plugs 275 and the upper interconnection lines 277 in the upper interconnection structure 270 and the arrangement form thereof can vary.

The upper bonding structure 280 is connected to the upper interconnection structure 270. For example, the gate contact stud 272 and the channel contact plug 271 are electrically connected to the upper bonding structure 280. The upper bonding structure 280 includes an upper bonding via 282, an upper bonding pad 284, and an upper bonding insulating layer 286. The upper bonding via 282 is connected to the upper interconnection structure 270. The upper bonding pad 284 is connected to the upper bonding via 282. The upper bonding via 282 and the upper bonding pad 284 include a conductive material, such as one of tungsten (W), copper (Cu), or aluminum (Al), etc., and each component further includes a diffusion barrier. The upper bonding insulating layer 286 also functions as a diffusion barrier for the upper bonding pad 284 and includes at least one of SiCN, SiO, SIN, SiOC, SiON or SiOCN. The upper bonding insulating layer 286 has a thickness that is less than a thickness of the upper bonding pad 284, but an embodiment thereof is not necessarily limited thereto.

FIG. 5 is an exploded perspective view of gate electrodes of a semiconductor device according to an embodiment.

In an embodiment, FIG. 5 illustrates a portion of gate electrodes 230 disposed between a pair of spaced apart isolation regions MS in FIG. 2A. In FIG. 5, the gate electrodes 230 are illustrated in a direction opposite to the stacking direction of the gate electrodes 230 illustrated in FIG. 3A.

Of the gate electrodes 230, upper gate electrode 230U disposed on an uppermost end (the lowermost end in FIG. 3A) are used as a string selection line. The upper gate electrode 230U is isolated into six sub-upper gate electrodes 230Ua, 230Ub, 230Uc, 230SUd, 230Ue, and 230Uf in the Y-direction by the second insulating regions SS. The sub-upper gate electrodes 230Ua, 230Ub, 230Uc, 230Ud, 230Ue, and 230Uf are connected to different contact plugs, and independently receive electrical signals. For example, of the gate electrodes 230, a gate electrode 230 on an uppermost end corresponds to the upper gate electrode 230U, but the number of the upper gate electrodes 230U can vary in some embodiments.

The central memory gate electrodes 230Mn disposed at a lower portion of the upper gate electrode 230U are disposed as a single flat layer without a groove. The lowermost memory gate electrode 230M0 is also disposed as a single layer without a groove. In FIG. 5, only the uppermost memory gate electrode 230Mn and the lowermost memory gate electrode 230M0 are illustrated for convenience of illustration, but similarly, each of the memory gate electrodes 230M forms a layer and is disposed without a groove. The memory gate electrodes 230Mn are configured as wordlines.

Of the gate electrodes 230, the lower gate electrodes 230L disposed at a lower portion of the memory gate electrodes 230M are used as a body selection line, and are divided into three sub-lower gate electrodes 230La, 230Lb, and 230Lc by the first insulating regions GS. The first insulating regions GS are disposed side by side in the X-direction, and the lower gate electrode 230L is completely divided in the Y-direction. The sub-lower gate electrodes 230La, 230Lb, and 230Lc are connected to different contact plugs and independently receive electrical signals. However, in some embodiments, the number of sub-lower gate electrodes 230La, 230Lb, and 230Lc disposed between a pair of adjacent isolation regions MS can vary.

For example, when an off voltage is applied to the lower gate electrode 230L, a bulk erase operation is performed by an erase voltage of the first material layer 203.

For example, the first insulating region GS and the second insulating region SS have a wavy shape, such that the first insulating region GS and the second insulating region SS can bend and cross a region between the channel structures CH, which are disposed in a zigzag pattern. Accordingly, the dummy channel structure DVH are not present between the first insulating region GS and the second insulating region SS, and the channel structures CH are disposed such that the distance between channel structures CH between which the first insulating region GS and the second insulating region SS pass and the distance between channel structures CH between which the first insulating region GS and the second insulating region SS do not pass is constant.

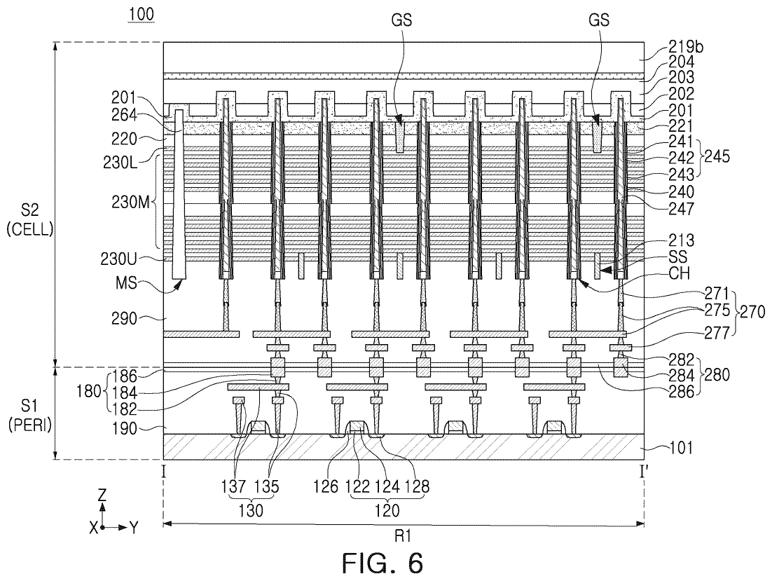

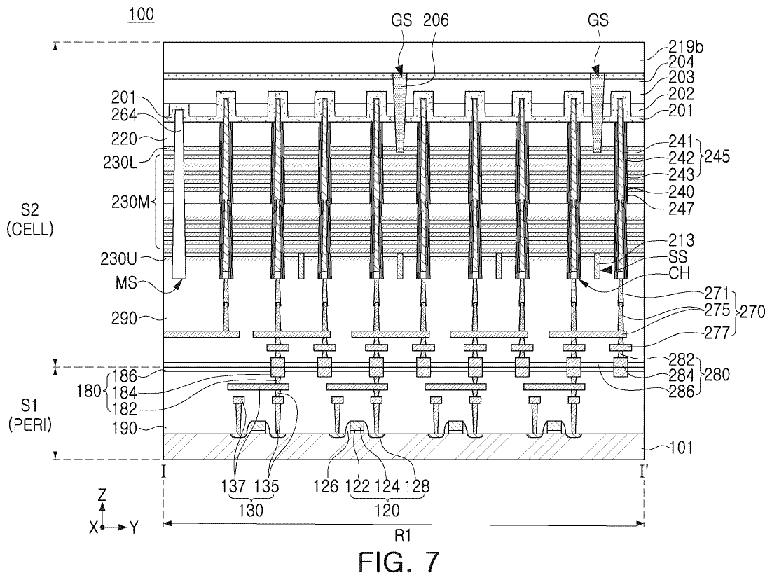

FIGS. 6 and 7 are cross-sectional views of a semiconductor device according to an embodiment. FIG. 6 illustrates a region that corresponds to FIG. 3B, and FIG. 7 illustrates a region that corresponds to FIG. 3A.

Referring to FIG. 6, in an embodiment, in the semiconductor device 100, the first insulating region GS is selectively disposed only below the buffer layer 201. For example, the first insulating region GS is recessed in the Z-direction below a lower portion of the buffer layer 201, in the opposite direction from the protrusion 240A of the channel layer 240 of the channel structure CH.

The first insulating region GS is disposed by selectively removing portions of the etch stop layer 221 to the lower gate electrode 230L at the uppermost end of the gate electrode 230. Accordingly, a lower end of the first insulating region GS is recessed into the interlayer insulating layer 220, which is a lower portion of the lower gate electrode 230L, as illustrated in FIG. 3B, and has an upper surface at a same level of the upper surface of the etch stop layer 221. Accordingly, the buffer layer 201 is disposed on the upper surface of the first insulating layer 206, which is disposed in the first insulating region GS.

Referring to FIG. 7, in an embodiment, in the semiconductor device 100, the etch stop layer 221 is not formed. For example, the interlayer insulating layer 220′ of the uppermost end above the lower gate electrode 230L has a thickness equal to or greater than the sum of the thicknesses of the interlayer insulating layer 220 and the etch stop layer 221 in FIG. 3B.

Accordingly, after forming the interlayer insulating layer 220′ to a sufficient thickness, when the sacrificial substrate is etched, the interlayer insulating layer 220′ is exposed and the channel protrusion 240A can be disposed.

For example, the first insulating region GS is selectively disposed only below the buffer layer 201 as illustrated in FIG. 6, and is removed from the upper conductive layer 204 above the second material layer 202. In addition, when the configurations in FIGS. 6 to 7 are used, the shape of the protrusion 240 of the channel layer 240 is not limited to the example in FIGS. 3C and 4A to 4C and can vary.

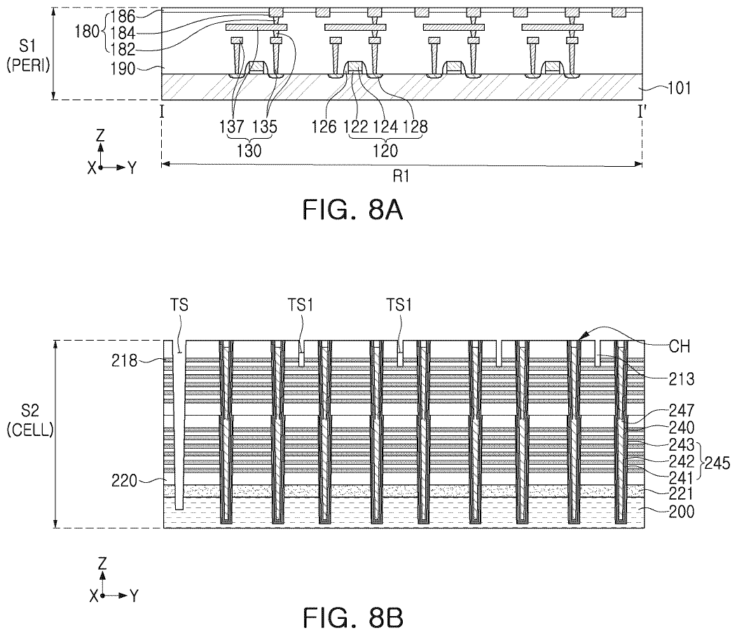

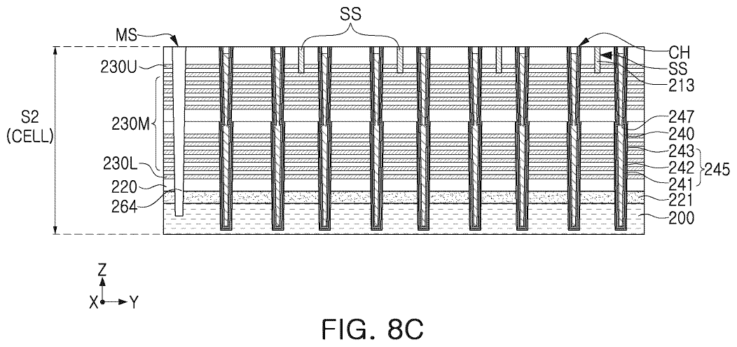

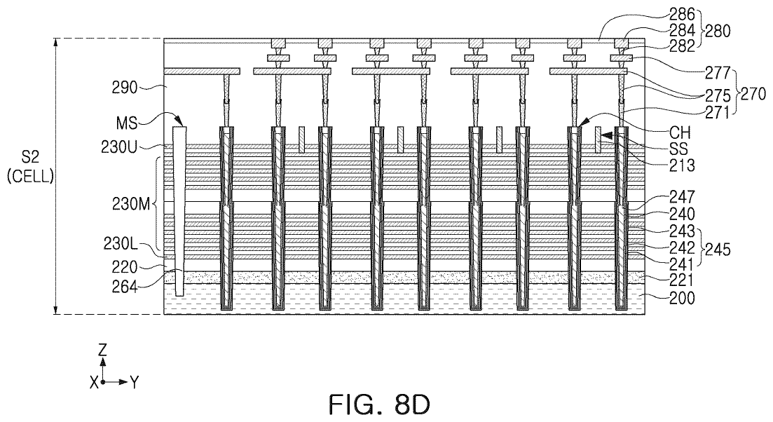

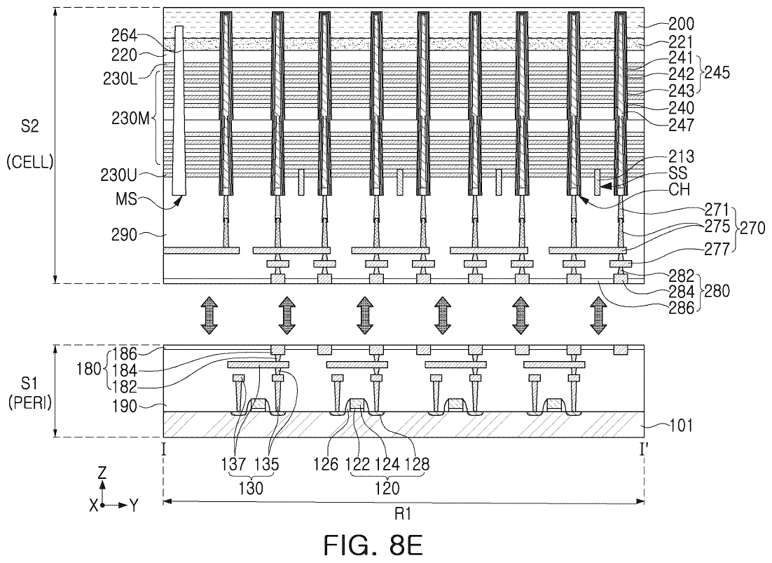

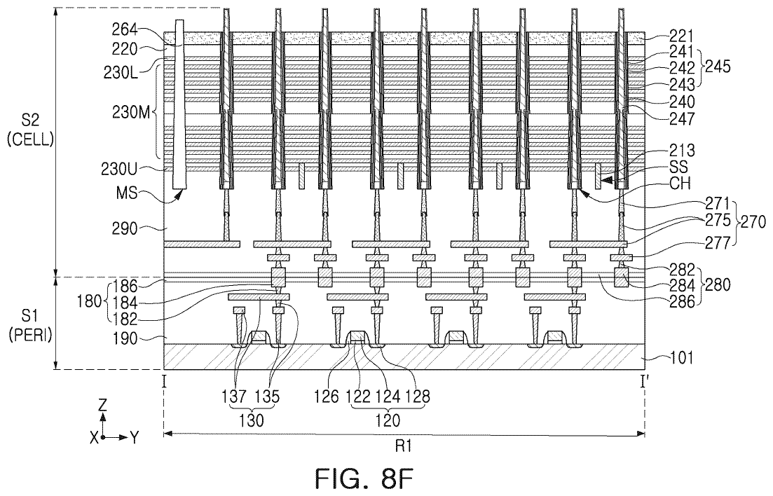

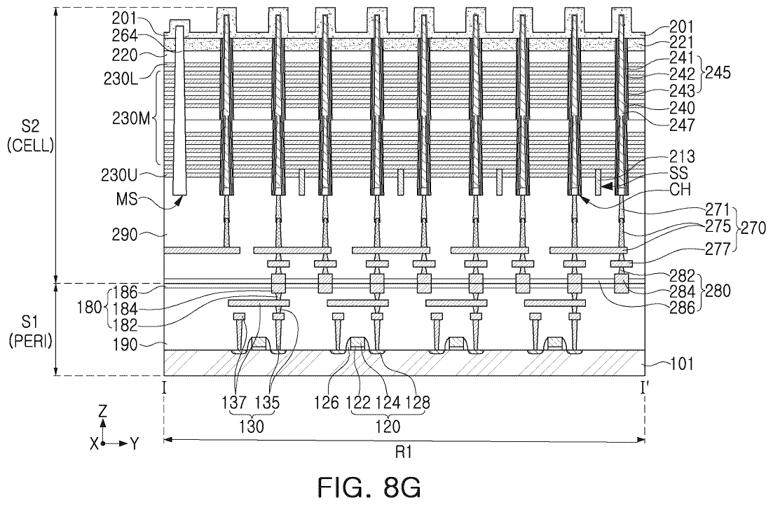

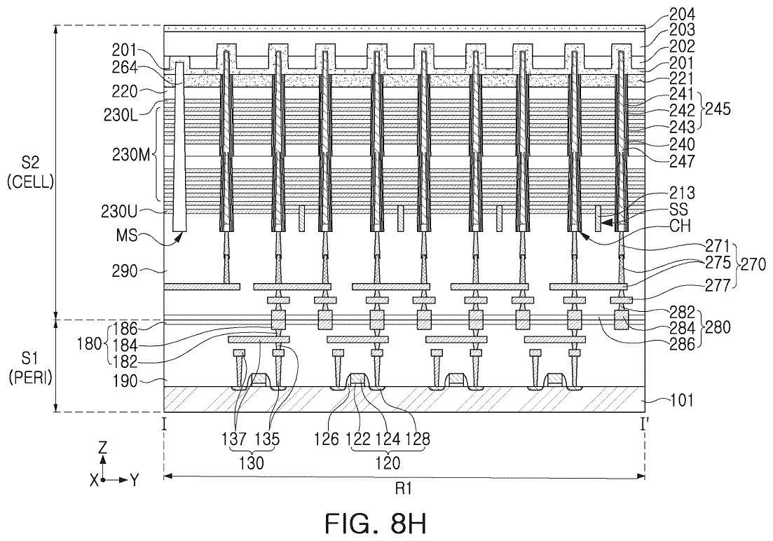

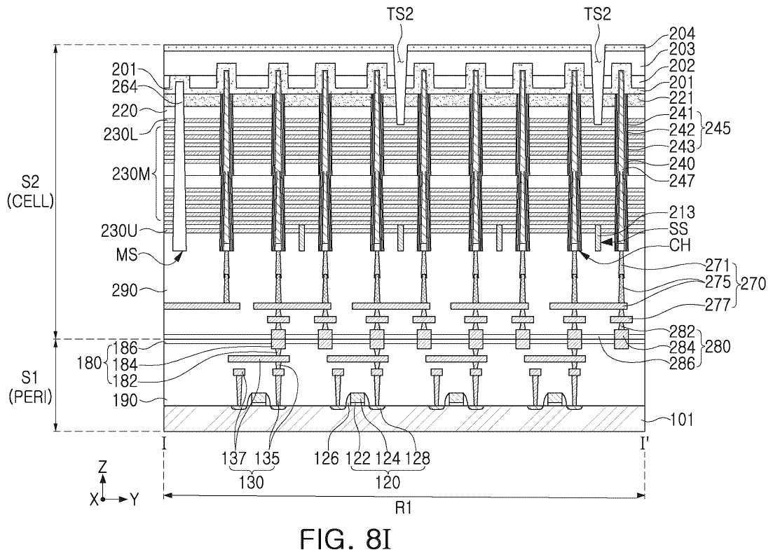

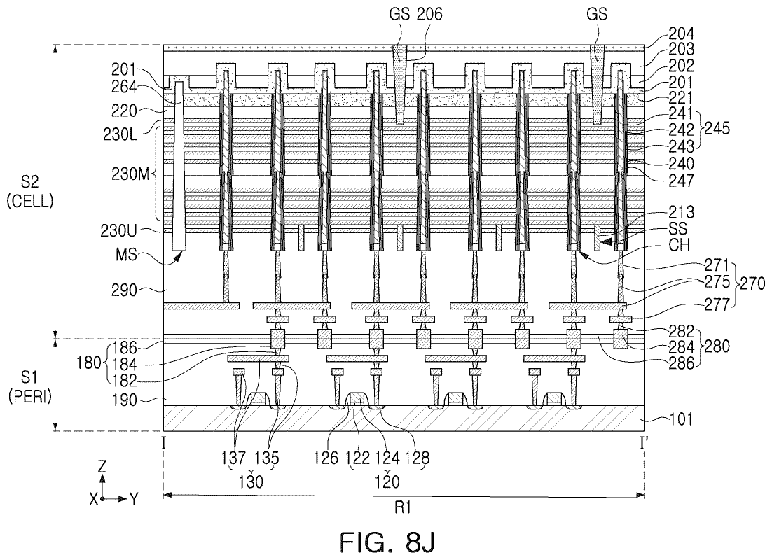

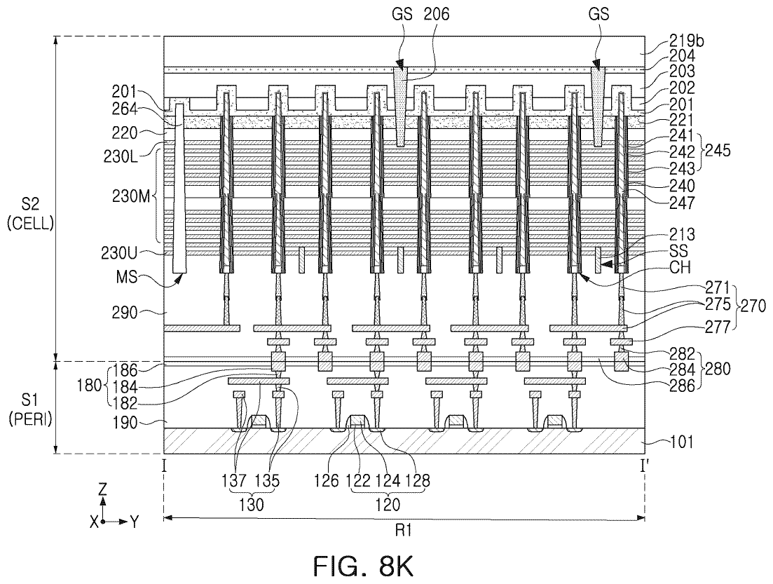

FIGS. 8A to 8K are cross-sectional views that illustrate a method of manufacturing a semiconductor device according to an embodiment, and illustrate a region that corresponds to FIG. 3B.

Referring to FIG. 8A, in an embodiment, a first semiconductor structure S1 (PERI) that includes circuit devices 120 that form a peripheral circuit region PERI, a lower interconnection structure 130, a lower bonding structure 180, and a lower capping layer 190, is formed on a first substrate 101.

Device isolation layers are formed in the first substrate 101, and a circuit gate dielectric layer 122 and a circuit gate electrode 124 are sequentially formed on the first substrate 101. The device isolation layers by, for example, a shallow trench isolation (STI) process. The circuit gate dielectric layer 122 is formed on the first substrate 101, and the circuit gate electrode 124 is formed on the circuit gate dielectric layer 122. The circuit gate dielectric layer 122 and the circuit gate electrode 124 can be formed using atomic layer deposition (ALD) or chemical vapor deposition (CVD). The circuit gate dielectric layer 122 are formed of silicon oxide, and the circuit gate electrode 124 are formed of at least one of polycrystalline silicon or a metal silicide layer, but an embodiment thereof is not necessarily limited thereto. Spacer layers 126 are formed on both sidewalls of the circuit gate dielectric layer 122 and the circuit gate electrode 124, and source/drain regions 128 are formed by injecting impurities into the active region of the first substrate 101 on both sides of the circuit gate electrode 124.

The lower contact plugs 135 of the lower interconnection structure 130 are formed by forming a portion of the lower capping layer 190, removing a portion thereof by etching and filling a conductive material therein. Lower interconnection lines 137 are formed by, for example, depositing a conductive material and patterning the material.

Of the lower bonding structures 180, the lower bonding via 182 is formed by forming a portion of the lower capping layer 190, removing a portion by etching, and filling a conductive material therein. The lower bonding pad 184 is formed by, for example, depositing a conductive material and patterning the material. The lower bonding structure 180 is formed by, for example, a deposition process or a plating process. The lower bonding insulating layer 186 can be formed by covering a portion of an upper surface and a side surface of the lower bonding pad 184 and performing a planarization process until the upper surface of the lower bonding pad 184 is exposed.

The lower capping layer 190 includes a plurality of insulating layers. The lower capping layer 190 is a portion in each of the processes that form the lower interconnection structure 130 and the lower bonding structure 180. Accordingly, the first semiconductor structure S1, which is the peripheral circuit region PERI, is formed.

Referring to FIG. 8B, the process of manufacturing the second substrate structure S2 (CELL) starts.

An etch stop layer 221 is formed on the base substrate 200, and the sacrificial insulating layers 118 and the interlayer insulating layers 220 are alternately stacked on the etch stop layer 221, thereby forming an upper stack structure.

Thereafter, channel structures CH that penetrate through the stack structure of the sacrificial insulating layers 218 and the interlayer insulating layers 220 are formed. In a region that corresponds to the isolation region MS (see FIG. 3B), an isolation opening TS that penetrates through the stack structure of the etch stop layer 221, the sacrificial insulating layers 218, and the interlayer insulating layers 220 is formed, and a first isolation opening TSI that penetrates through the upper sacrificial insulating layer 218 is formed in a region that corresponds to the second insulating region SS.

The base substrate 200 includes a semiconductor material, such as one of a group IV semiconductor, a group III-V compound semiconductor, or a group II-VI compound semiconductor. The etch stop layer 221 is a layer that terminates etching by etch selectivity when the base substrate 200 is removed, which will be described below. For example, when the base substrate 200 is a single crystal or an amorphous semiconductor, the etch stop layer 221 is formed as a polycrystalline semiconductor layer.

A portion of the sacrificial insulating layers 218 are replaced with gate electrodes 230 (see FIG. 3A) through a subsequent process. The sacrificial insulating layers 218 are formed of a material that differs from that of the interlayer insulating layers 220, and are formed of a material with etch selectivity under specific etching conditions with respect to the interlayer insulating layers 220. For example, the interlayer insulating layer 220 is formed of at least one of silicon oxide or silicon nitride, and the sacrificial insulating layers 218 is formed of a material different from that of the interlayer insulating layer 220, that is one or more of silicon, silicon oxide, silicon carbide, or silicon nitride. In embodiments, the thickness of the interlayer insulating layers 220 are not the same. The thickness of the interlayer insulating layers 220 and the sacrificial insulating layers 218 and the number of films included therein can vary from the illustrated examples.

As illustrated in FIG. 6, the interlayer insulating layer 220′ (uppermost interlayer insulating layer) in contact with the base substrate 200 has a thickness greater than that of the other interlayer insulating layer 220 without the etch stop layer 221, but an embodiment thereof is not necessarily limited thereto.

In the second region R2, a photolithography process and an etching process are repeatedly performed on the sacrificial insulating layers using a mask layer such that the sacrificial insulating layers 218 in an upper portion extend shorter than the sacrificial insulating layers 218 in a lower portion. Accordingly, the sacrificial insulating layers 218 form a step structure with a staircase shape that has a predetermined unit.

Vertical sacrificial structures are formed that penetrate through the lower stack structure. The vertical sacrificial structures are formed by anisotropically etching the lower stack structure of the sacrificial insulating layers 218 and the interlayer insulating layers 220 using a mask layer, forming hole-shaped channel holes and filling the holes. The vertical sacrificial structures are recessed into the base substrate 200 at a uniform depth, but an embodiment thereof is not necessarily limited thereto. The vertical sacrificial structure includes a semiconductor material such as polycrystalline silicon. According to an embodiment, the vertical sacrificial structure includes at least one of silicon oxide, silicon nitride, or silicon oxynitride. After forming the vertical sacrificial structure, an upper stack structure of the sacrificial insulating layers 218 and the interlayer insulating layers 220is formed on the lower stack structure and the vertical sacrificial structure.

When a channel hole that forms a vertical sacrificial structure is formed, a sacrificial blocking structure is preferentially formed that maintains a recess depth of the channel hole into the base substrate to be uniform.

A sacrificial blocking structure is formed in the position where a channel hole is formed in the base substrate 200 by using a material that is etch selectivity with respect to the base substrate 200 for the anisotropic etching. For example, the structure is a metal. When a channel hole is formed when the sacrificial blocking structure is formed in each channel hole, the channel hole is not formed in a region below the sacrificial blocking structure due to the sacrificial blocking structure. Thereafter, the sacrificial blocking structure is removed through the channel hole, and depending on the shape of the sacrificial blocking structure, a channel structure CH having a head 240C is formed as illustrated in FIG. 4A or FIG. 4C.

An upper capping layer 290 that covers the stack structure of the sacrificial insulating layers 218 and the interlayer insulating layers 220 is partially formed.

The channel structures CH are formed by forming upper holes in a vertical sacrificial structure, forming hole-shaped channel holes by removing the vertical sacrificial structure, and filling the channel holes with a plurality of layers. The plurality of layers include the data storage structure 245, the channel layer 240, the filling insulating layer 247, and the channel pad 249. The upper channel holes of the channel holes are formed by anisotropically etching the upper stack structure of the sacrificial insulating layers 218 and the interlayer insulating layers 220 using a mask layer. The lower channel holes of the channel holes are formed by removing the vertical sacrificial structure exposed through the upper channel holes.

Due to the height of the stack structure, a sidewall of the channel structures CH is not perpendicular to an upper surface of the base substrate 200. The channel structures CH are formed to be recessed into a portion of the base substrate 200, depending on the depth of the channel hole.

The data storage structure 245 is formed to have a uniform thickness. In this process, the entirety or a portion of the data storage structure 245 is formed, and a portion that extends perpendicular to the base substrate 200 along the channel structures CH is also formed. The channel layer 240 is formed on a data storage structure 245 in the channel structures CH. The filling insulating layer 247 is formed to fill the channel structures CH and includes an insulating material. The channel pad 249 is formed of a conductive material, such as polycrystalline silicon.

As illustrated in FIGS. 4B and 4C, when the channel structure 246 is formed in the protrusion 240 of the channel structures CH, before forming the channel layer 240 and when the data storage structure 245 is formed, channel layer materials such as silicon are grown is the region in the base substrate 200 through selective epitaxial growth (SEG), and the channel structure 246 is formed at a channel end to have a pillar shape, rather than an annular shape.

Referring back to FIG. 8C, in an embodiment, the sacrificial insulating layers (218 in FIG. 8B) are removed through an isolation opening (TS in FIG. 8B) and gate electrodes 230 are formed by depositing a conductive material. An isolation region MS is formed in the isolation opening (TS in FIG. 8B), and a second insulating region SS is formed in the first isolation opening TS1.

The conductive material includes one of a metal, polycrystalline silicon, or a metal silicide. After forming the gate electrodes 230, the conductive material deposited in the isolation opening TS is removed through an additional process, the isolation region MS is formed by filling an insulating material and a conductive material, and the second insulating region SS is formed by filling the first isolation opening TSI with an insulating material.

Referring to FIG. 8D, and FIG. 3A, in an embodiment, an upper interconnection structure 270 that includes gate contact plugs 252 and channel contact plugs 271 are formed, and an upper bonding structure 280 is formed.

In the first region R1, the channel contact plugs 271 are connected to the channel structures CH. In the second region R2, the gate contact plugs 252 are connected to the gate electrodes 230. The gate contact plugs 252 are formed at different depths, or are formed by simultaneously forming contact holes using an etch stop layer, and filling the contact holes with a conductive material.

The contact studs 272 are connected to the gate contact plugs 252. The upper contact plugs 275 are formed on the contact studs 272, and vertically connect the upper interconnection lines 277 to each other.

The upper bonding structure 280 is formed in a similar manner to the lower bonding structure 180. Accordingly, a second semiconductor structure S2, which is a memory cell region CELL, is formed. However, during a process of manufacturing a semiconductor device, the memory cell region CELL further includes the base substrate 200.

Referring to FIG. 8E, in an embodiment, the first semiconductor structure S1, which is the peripheral circuit region PERI, and the second semiconductor structure S2, which is the memory cell region CELL, are bonded to each other.

The peripheral circuit region PERI and the memory cell region CELL are connected to each other by bonding the lower bonding pad 184 to the upper bonding pad 284 by applying pressure. The lower bonding insulating layer 186 and the upper bonding insulating layer 286 are connected to each other by bonding with pressure. The memory cell region CELL is turned upside down and bonded to the peripheral circuit region PERI such that the upper bonding pad 284 face downward. The peripheral circuit region PERI and the memory cell region CELL are directly bonded to each other without using an adhesive, such as an adhesive layer, therebetween.

Referring to FIG. 8F, in an embodiment, the data storage structure 245 on the base substrate 200 and the channel structure CH is removed. First, the base substrate 200 is removed. A portion of the base substrate 200 is removed from an upper surface by a polishing process such as a grinding process, the other portion is removed by an etching process such as wet etching and/or dry etching, and is etched until the etch stop layer 221 is upwardly exposed. However, in some embodiments, the entire base substrate 200 is removed through an etching process. In the region from which the base substrate 200 was removed, the channel structures CH has a protruding second portion.

The data storage structure 245 on the second portion of the channel structure CH is removed. The data storage structure 245 is removed by a photolithography process and an etching process such as wet etching and/or dry etching. Accordingly, in the second portion of the channel structure CH protruding to the etch stop layer 221, preferably to the stack structure, the channel layer 240 is exposed and the protrusion 240A is disposed. Accordingly, when a subsequent process is performed, the channel layer 240 of the second portion is in direct contact with the buffer layer 201.

Referring to FIG. 8G, in an embodiment, a buffer layer 201 is formed on the protrusion 240A and the etch stop layer 221 of the channel layer 240 of the channel structure CH.

The buffer layer 201 is formed as, for example, a crystalline silicon layer or an epitaxial layer. In this process, the etch stop layer 221 formed at a lower portion of the buffer layer 201 is replaced by forming the uppermost interlayer insulating layer 220 to have a relatively great thickness as illustrated in FIG. 7. The buffer layer 201 is formed to conformally cover the protrusion 240A of the channel layer 240.

As illustrated in FIG. 8H, in an embodiment, a second material layer 202, a first material layer 203 and an upper conductive layer 204 are consecutively formed to have a first thickness above the buffer layer 201.

The second material layer 202 is deposited in-situ and includes N-type impurities that have a second conductivity, and is formed as a crystalline silicon layer, such as a polycrystalline silicon layer. The first thickness of the second material layer 202 is less than the height of the protrusion 240A of the channel layer 240, such that both the end of the protrusion 240A of the channel layer 240 and the side surface thereof are exposed above the second material layer 202.

The second material layer 202 and the protrusion 240A of the channel layer 240 are electrically connected through the side surface of the channel layer that corresponds to the first thickness of the second material layer 202, and are electrically connected through the buffer layer 201.

A first material layer 203 is formed on the second material layer 202.

The first material layer 203 is formed to cover at least a portion of area of the second material layer 202 and has an area less than that of the second material layer 202.

The first material layer 203 is a crystalline silicon layer deposited in-situ and includes P-type impurities that have a first conductivity, such as a polycrystalline silicon layer.

The first material layer 203 is formed to have a thickness sufficient to cover an end of the protrusion 240A of the channel layer 240 and overlaps the protrusion 240A in the Z-direction. Accordingly, the first material layer 203 and the channel layer 240 are electrically connected to each other through the buffer layer 201.

The first material layer 203 extends to a boundary between the first region R1 and the second region R2, and the second material layer 202 extends further toward the second region R2 and has an area greater than that of the first material layer 203.

An upper conductive layer 204 is further formed on the first material layer 203.

The upper conductive layer 204 is formed by depositing a conductive material, such as a metal such as aluminum (Al) or tungsten (W), on the first material layer 203, and is formed to have the same area as the first material layer 203.

For example, a horizontal insulating layer 219a that covers the second region R2 is formed to correspond to the level of the second material layer 203. The horizontal insulating layer 219a has a multilayered structure, but an embodiment thereof is not necessarily limited thereto.

The horizontal insulating layer 219A is formed of the same material as the sacrificial insulating layers 118, but an embodiment thereof is not necessarily limited thereto, and is formed while being in contact with the first and second material layers 203 and 202 in a region without the buffer layer 201.

Referring to FIG. 8I, a second insulating opening TS2 that corresponds to the first insulating region GS in FIG. 2A is formed on the upper conductive layer 204.

The second insulating opening TS2 penetrates from the upper conductive layer 204 to the lower gate electrode 230L. On the X-Y plane, the second insulating opening TS2 has a wavy shape and extends in the X-axis direction and has a width that decreases in the Z-axis direction.

Due to the second insulating opening TS2, the lower gate electrode 230L has a shape cut to a predetermined capacity as illustrated in FIG. 5, and the gate electrode disposed thereon does not have an insulating region above the second insulating opening TS2.

The second insulating opening TS2 is spaced apart from the channel structure CH formed in the first region RI by a predetermined distance d1 or more.

In addition, the second insulating opening TS2, is formed by selectively removing the remaining layers in which the channel structure CH is not formed. A channel structure CH of sufficient capacity can be assured and the lower gate electrode 230L is cut. As illustrated in FIG. 8J, the first insulating layer 206 is formed to have an upper surface coplanar with an upper surface of the upper conductive layer 204 while filling the second insulating opening TS2.

The process of forming the first insulating region GS by filling the first insulating layer 206 in the second insulating opening TS2 is performed simultaneously with the process of forming the horizontal insulating layer 219b. For example, the horizontal insulating layer 219b and the first insulating layer 206 of the first insulating region GS are formed of the same material.

Thereafter, as illustrated in FIG. 8K, in an embodiment, upper patterns 253 and 254 and a passivation layer 219b may be formed.

A passivation layer 219b is formed on the first region R1 and the second region R2. For example, the passivation layer is implemented in multiple layers. After forming a lower portion of the passivation layer 219b, a via hole that opens the upper conductive layer 204 and the second material layer 202 is formed, and each of the source contact via 267 and the body contact via 268 is formed in the via hole. The source interconnection 253 is formed in contact with the source contact via 267, each body interconnection 254 is formed in contact with the body contact via 268, and an upper portion is formed. The passivation layer 219b is flattened by a polishing process such as a grinding process or a chemical mechanical polishing process. A process of removing a portion of the passivation layer 219b and forming an input/output pad may be added as a subsequent process, but an embodiment thereof is not necessarily limited thereto.

The semiconductor device of embodiments illustrated in FIGS. 2A to 7 can be manufactured by processes illustrated by FIGS. 8A to 8K.

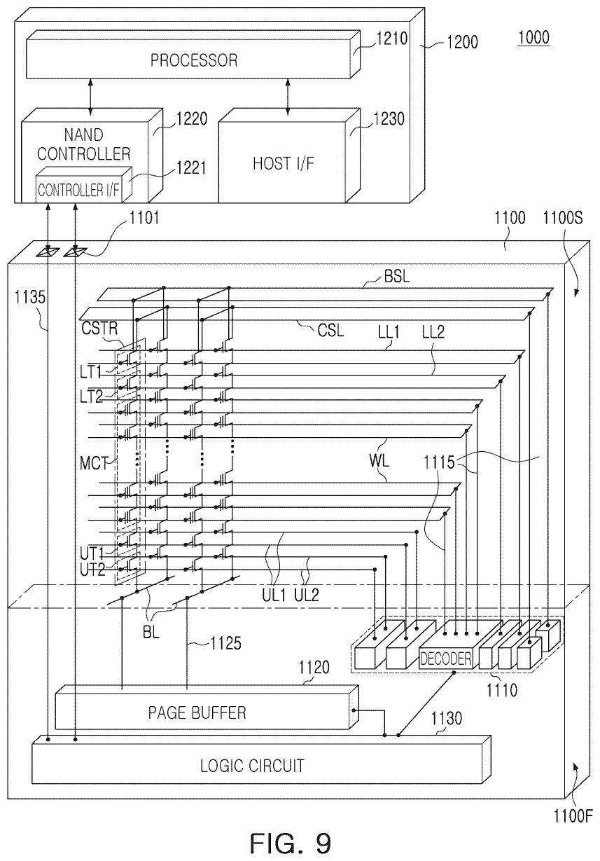

FIG. 9 illustrates a data storage system that includes a semiconductor device according to an embodiment.

Referring to FIG. 9, in an embodiment, a data storage system 1000 includes a semiconductor device 1100 and a controller 1200 electrically connected to the semiconductor device 1100. The data storage system 1000 may be a storage device that includes one or a plurality of semiconductor devices 1100 or an electronic device that includes a storage device. For example, the data storage system 1000 may be implemented as a solid state drive device (SSD) that includes one or more semiconductor devices 1100, a universal serial bus (USB), a computing system, a medical device, or a communication device.

The semiconductor device 1100 may be implemented as a non-volatile memory device, such as a NAND flash memory device described in an aforementioned embodiment with reference to FIGS. 1 to 3C. The semiconductor device 1100 includes a first structure 1100F and a second structure 1100S on the first structure 1100F. In embodiments, the first structure 1100F is disposed on the side of the second structure 1100S. The first structure 1100F is implemented as a peripheral circuit structure that includes a decoder circuit 1110, a page buffer 1120, and a logic circuit 1130. The second structure 1100S is implemented as a memory cell structure that includes a bitline BL, a common source line CSL, a body select lines BSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR includes lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 can vary in embodiments.

In embodiments, the upper transistors UT1 and UT2 include a string select transistor, and the lower transistors LT1 and LT2 include a ground select transistor. The gate lower lines LL1 and LL2 are gate electrodes of the lower transistors LT1 and LT2, respectively. The wordlines WL are gate electrodes of the memory cell transistors MCT, and the gate upper lines UL1 and UL2 are gate electrodes of the upper transistors UT1 and UT2, respectively.

In embodiments, the lower transistors LT1 and LT2 include a lower erase control transistor LT1 and a ground select transistor LT2 connected to each other in series. The upper transistors UT1 and UT2 include a string select transistor UT1 and an upper erase control transistor UT2 connected to each other in series. At least one of the lower erase control transistor LT1 and the upper erase control transistor UT2 is used in an erase operation that erases data stored in the memory cell transistors MCT using a GIDL phenomenon.

The common source line CSL, the first and second gate lower lines LL1 and LL2, the wordlines WL, and the first and second gate upper lines UL1 and UL2 are electrically connected to the decoder circuit 1110 through first connection interconnections 1115 that extend from the first structure 1100F to the second structure 1100S. The bitlines BL are electrically connected to the page buffer 1120 through second connection interconnections 1125 that extend from the first structure 110F to the second structure 1100S.

In the first structure 1100F, the decoder circuit 1110 and the page buffer 1120 perform control operations on at least one selected memory cell transistor MCT. The decoder circuit 1110 and the page buffer 1120 are controlled by the logic circuit 1130. The semiconductor device 1100 communicates with the controller 1200 through an input/output pad 1101 electrically connected to the logic circuit 1130. The input/output pads 1101 are electrically connected to the logic circuit 1130 through an input/output connection line 1135 that extends from the first structure 1100F to the second structure 1100S.

The controller 1200 includes a processor 1210, a NAND controller 1220, and a host interface 1230. In embodiments, the data storage system 1000 includes a plurality of semiconductor devices 1100, and the controller 1200 controls the plurality of semiconductor devices 1100.

The processor 1210 controls an overall operation of the data storage system 1000 that includes the controller 1200. The processor 1210 operates according to a predetermined firmware, and accesses the semiconductor device 1100 by controlling the NAND controller 1220. The NAND controller 1220 includes a controller interface 1221 that processes communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 can be transmitted. The host interface 1230 provides a communication function between the data storage system 1000 and an external host. When a control command from an external host is received through the host interface 1230, the processor 1210 controls the semiconductor device 1100 in response to the control command.

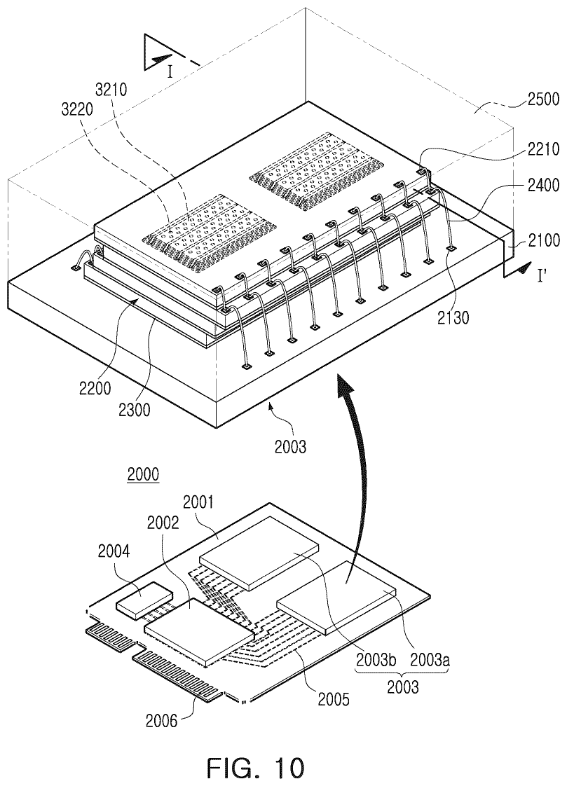

FIG. 10 is a perspective view of a data storage system that includes a semiconductor device according to an embodiment.

Referring to FIG. 10 a data storage system 2000 in an embodiment includes a main board 2001, a controller 2002 mounted on the main board 2001, one or more semiconductor packages 2003, and a DRAM 2004. The semiconductor package 2003 and the DRAM 2004 are connected to the controller 2002 by interconnection patterns 2005 formed on the main board 2001.

The main board 2001 includes a connector 2006 that includes a plurality of pins coupled to an external host. The number and arrangement of the plurality of pins in the connector 2006 varies depending on a communication interface between the data storage system 2000 and the external host. In embodiments, the data storage system 2000 can communicate with an external host according to one of a universal serial bus (USB), a peripheral component interconnect express (PCI-Express), a serial advanced technology attachment (SATA), or an M-Phy for universal flash storage (UFS). In embodiments, the data storage system 2000 operates by power supplied from an external host through the connector 2006. The data storage system 2000 may further include a power management integrated circuit (PMIC) that distributes the power received from the external host to the controller 2002 and the semiconductor package 2003.

The controller 2002 writes data to or reads data from the semiconductor package 2003, and can increase an operating speed of the data storage system 2000.

The DRAM 2004 is a buffer memory that compensates for differences in speed between the semiconductor package 2003, which is a data storage space, and an external host. The DRAM 2004 in the data storage system 2000 may operate as a cache memory, and may provide a space for temporarily storing data in a control operation for the semiconductor package 2003. When the data storage system 2000 includes the DRAM 2004, the controller 2002 further includes a DRAM controller that controls the DRAM 2004, in addition to a NAND controller that controls the semiconductor package 2003.

The semiconductor package 2003 includes first and second semiconductor packages 2003a and 2003b spaced apart from each other. Each of the first and second semiconductor packages 2003a and 2003b is a semiconductor package that includes a plurality of semiconductor chips 2200. Each of the first and second semiconductor packages 2003a and 2003b includes a package substrate 2100, semiconductor chips 2200 on the package substrate 2100, adhesive layers 2300 disposed on lower surfaces of the semiconductor chips 2200, a connection structure 2400 that electrically connects the semiconductor chips 2200 to the package substrate 2100, and a molding layer 2500 that covers the semiconductor chips 2200 and the connection structure 2400 on the package substrate 2100.

The package substrate 2100 is configured as a printed circuit board that includes package upper pads 2130. Each semiconductor chip 2200 includes an input/output pad 2210. The input/output pad 2210 corresponds to the input/output pad 1101 in FIG. 9, and includes the conductive pad 300 in FIG. 1. Each of the semiconductor chips 2200 includes gate stack structures 3210 and channel structures 3220. Each of the semiconductor chips 2200 includes the semiconductor device described in an aforementioned embodiment with reference to FIGS. 1 to 8.

In embodiments, the connection structure 2400 is a bonding wire that electrically connects the input/output pad 2210 to the upper package pads 2130. Accordingly, in each of the first and second semiconductor packages 2003a and 2003b, the semiconductor chips 2200 are electrically connected to each other by a bonding wire method, and are electrically connected to the package upper pads 2130 of the package substrate 2100. In other embodiments, in each of the first and second semiconductor packages 2003a and 2003b, the semiconductor chips 2200 are electrically connected to each other by a connection structure that includes a through-electrode (TSV) instead of the connection structure 2400 of a bonding wire method.

In embodiments, the controller 2002 and the semiconductor chips 2200 are included in a single package. In an embodiment, the controller 2002 and the semiconductor chips 2200 are mounted on an interposer substrate that differs from the main board 2001, and the controller 2002 and the semiconductor chips 2200 are connected to each other by interconnection formed on the interposer substrate.

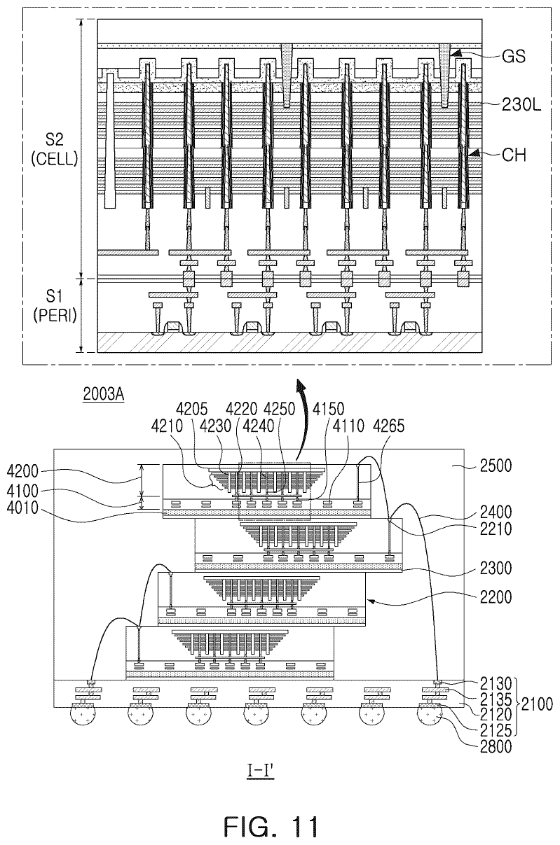

FIG. 11 is a cross-sectional view of a semiconductor package according to an embodiment.

FIG. 11 is a cross sectional view of the semiconductor package 2003 in FIG. 10 taken along line III-III′.

Referring to FIG. 11, in an embodiment, in the semiconductor package 2003A, the package substrate 2100 is implemented as a printed circuit substrate. The package substrate 2100 includes a package substrate body portion 2120, package upper pads 2130 disposed on an upper surface of the package substrate body portion 2120 (see FIG. 10), lower pads 2125 disposed on the lower surface of the package substrate body 2120 or exposed through the lower surface, and internal interconnections 2135 that electrically connect the upper pads 2130 to the lower pads 2125 in the package substrate body 2120. The lower pads 2125 are connected to the interconnection patterns 2005 of the main the substrate 2001 of the data storage system 2000 through conductive connection portions 2800 as illustrated in FIG. 11.

In the semiconductor package 2003A, each of the semiconductor chips 2200A includes a semiconductor substrate 4010, a first semiconductor structure 4100 disposed on the semiconductor substrate 4010, and a second semiconductor structure 4200 bonded to the first semiconductor structure 4100 by wafer bonding on the first semiconductor structure 4100.

The first semiconductor structure 4100 includes a peripheral circuit region that includes a peripheral interconnection 4110 and a lower bonding structure 4150. The second semiconductor structure 4200 includes a common source line 4205, a gate stack structure 4210 interposed between the common source line 4205 and the first semiconductor structure 4100, a channel structure 4220 and an isolation structure 4230 that penetrate through the gate stack structure 4210, and an upper bonding structure 4250 that is electrically connected to wordlines of the channel structures 4220 and the gate stack structure 4210. For example, the upper bonding structure 4250 is electrically connected to the channel structures 4220 and wordlines through the gate contact plugs 252, which are electrically connected to bitlines 4240 and wordlines. The lower portion bonding structure 4150 of the first semiconductor structure 4100 and the upper bonding structure 4250 of the second semiconductor structure 4200 are bonded to each other while being in contact with each other. The bonded portions of the lower bonding structure 4150 and the upper bonding structure 4250 are formed of copper (Cu), for example.

The second semiconductor structure 4200 further includes a first insulating region GS as illustrated in the enlarged view. Each of the semiconductor chips 2200A includes at least one first insulating region GS that penetrates through and isolates the lower gate electrode 230L.

Each of the semiconductor chips 2200A further includes an input/output pad 2210 and an input/output interconnection 4265 below the input/output pad 2210. The input/output connection interconnection 4265 is electrically connected to a portion of the second bonding structures 4210. The input/output pad 2210 includes a conductive pad 300.

The semiconductor chips 2200A in FIG. 11 are electrically connected to each other by connection structures 2400 in the form of bonding wires. However, in some embodiments, semiconductor chips in a semiconductor package, such as the semiconductor chips 2200A in FIG. 11, are electrically connected to each other by a connection structure that includes a through electrode TSV.

According to aforementioned embodiments, in a structure in which two or more substrate structures are bonded to each other, a bulk erase operation can be performed by implementing a common source line and a body selection line to allow the common source line and the body selection line to be simultaneously in contact with the channel layer exposed on the backside surface of the upper substrate structure. In addition, by forming an insulating region that extends from the backside surface of the upper substrate structure and penetrates through at least one gate electrode has a wavy shape pass between the channel structures, the capacity of the channel structure can be assured. Accordingly, a semiconductor device that has increased reliability and integration density and a data storage system that includes the same can be provided.

While embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure that includes a first substrate, circuit devices disposed on the first substrate, a lower interconnection structure electrically connected to the circuit devices, and a lower bonding structure connected to the lower interconnection structure; and
a second semiconductor structure disposed on and connected to the first semiconductor structure,
wherein the second semiconductor structure includes:
a stack structure that includes interlayer insulating layers and gate electrodes stacked in a vertical direction;
channel structures that each include a first portion that penetrates through the stack structure in a vertical direction and a second portion that extends upward from the first portion;
an upper interconnection structure disposed below the stack structure;
an upper bonding structure connected to the upper interconnection structure and bonded to the lower bonding structure;
a first material layer disposed on the stack structure and the channel structures and that has a first conductivity; and
a second material layer disposed between the first material layer and the stack structure and that has a second conductivity that differs from the first conductivity,
wherein the first material layer overlaps the second portion of the channel structures in the vertical direction, and the second material layer does not overlap the second portion of the channel structures in the vertical direction.

2. The semiconductor device of claim 1,
wherein the first material layer includes a silicon layer that has a P-type conductivity, and
wherein the second material layer includes a silicon layer that has an N-type conductivity.

3. The semiconductor device of claim 2, further comprising:
a buffer layer disposed between the second material layer and the stack structure, between the second material layer and the second portions of the channel structures, and between the first material layer and the second portions of the channel structures.

4. The semiconductor device of claim 3, wherein the buffer layer includes an undoped silicon layer.

5. The semiconductor device of claim 3, wherein each of the channel structures includes:
an insulating core region;
a channel layer disposed on a side surface and an upper surface of the insulating core region;
a data storage structure interposed between an outer side surface of the channel layer and the stack structure,
wherein upper ends of data storage structures of the channel structures are disposed below the buffer layer,
wherein the buffer layer is in contact with the channel layers of the channel structures, and
wherein the first and second material layers are spaced apart from the channel layers of the channel structures by the buffer layer.

6. The semiconductor device of claim 5, wherein each of the second portions of the channel structures includes a lower region and an upper region disposed on the lower region, wherein a width of the upper region is greater than a width of the lower region.

7. The semiconductor device of claim 1, wherein the second material layer includes openings, and the openings of the second material layer surround side surfaces of the second portions of the channel structures.

8. The semiconductor device of claim 1, wherein upper surfaces of the second portions of the channel structures are located at a higher level than an upper surface of the second material layer.

9. The semiconductor device of claim 1, further comprising:
isolation regions; and
at least one upper insulating region,
wherein the gate electrodes include:
one or more lower gate electrodes;
a plurality of intermediate gate electrodes disposed on the one or more lower gate electrodes; and
one or more upper gate electrodes disposed on the plurality of intermediate gate electrodes,
wherein the one or more upper gate electrodes are adjacent to the second material layer,
wherein the isolation regions penetrate through a stack structure in the vertical direction, and
wherein the at least one upper insulating region is disposed at a higher level than the plurality of intermediate gate electrodes, and penetrates the one or more upper gate electrodes in the vertical direction.

10. The semiconductor device of claim 9,
wherein each of the isolation regions extends in a first direction,
wherein the one or more upper gate electrodes are divided in a second direction perpendicular to the first direction by the at least one upper insulating region, and
wherein the at least one upper insulating region has a wavy shape in a plan view.

11. The semiconductor device of claim 9, wherein the at least one upper insulating region extends upward from a portion that penetrates through the one or more upper gate electrodes and penetrates the first and second material layers.

12. The semiconductor device of claim 9, further comprising:
a plurality of lower insulating regions disposed at a lower level than the plurality of intermediate gate electrodes and that penetrate through the one more lower gate electrodes in the vertical direction.

13. The semiconductor device of claim 12,
wherein the plurality of lower insulating regions include:
at least one first lower insulating region that overlaps the at least one upper insulating region in the vertical direction; and
a second lower insulating region that does not overlap the at least one upper insulating region in the vertical direction.

14. The semiconductor device of claim 1,
wherein each of the channel structures includes:
an insulating core region;
a channel layer disposed on a side surface of the insulating core region;
a pad pattern disposed on the insulating core region and the channel layer; and
a data storage structure interposed between an outer side surface of the channel layer and the stack structure,
wherein the pad patterns are disposed in the second portions of the channel structures, and
wherein each of the pad patterns includes a semiconductor material layer.

15. The semiconductor device of claim 14, wherein the semiconductor material layer includes undoped silicon.

16. A semiconductor device, comprising:
a stack structure that includes interlayer insulating layers and gate electrodes stacked in a vertical direction;
a first material layer disposed on the stack structure and that includes a first semiconductor material that has a first conductivity;
a second material layer disposed between the first material layer and the stack structure and that includes a second semiconductor material that has a second conductivity that differs from the first conductivity;
channel structures that each include a first portion that penetrates through the stack structure in the vertical direction, and a second portion that extends upward from the first portion, penetrates through the second material layer, and is disposed below the first material layer; and
a buffer layer disposed between second portion of the channel structures and the second material layer, and between the second portion of the channel structures and the first material layer.

17. The semiconductor device of claim 16,
wherein each of the channel structures includes a channel layer, and the channel layers of the second portions of the channel structures are in contact with the buffer layer, and
wherein upper surfaces of the second portions of the channel structures are located at a higher level than an upper surface of the second material layer.

18. The semiconductor device of claim 17,
wherein the first material layer is a silicon layer that has a P-type conductivity,
wherein the second material layer is a silicon layer that has an N-type conductivity, and
wherein the buffer layer is an undoped silicon layer.

19. A data storage system, comprising:
a semiconductor storage device that includes a first semiconductor structure that includes a substrate and circuit devices disposed on the substrate; a second semiconductor structure that includes a stack structure that includes interlayer insulating layers and gate electrodes stacked in a vertical direction and channel structures that penetrate through the stack structure; and an input/output pad electrically connected to the circuit devices; and
a controller that is electrically connected to the semiconductor storage device through the input/output pad and that controls the semiconductor storage device,
wherein the first semiconductor structure further includes:
a lower interconnection structure that is electrically connected to the circuit devices; and
a lower bonding structure connected to the lower interconnection structure,
wherein the second semiconductor structure includes:
an upper interconnection structure disposed below the stack structure;
an upper bonding structure connected to the upper interconnection structure and bonded to the lower bonding structure;
a first material layer disposed on the stack structure and the channel structure and that has a first conductivity; and
a second material layer disposed between the first material layer and the stack structure and that has a second conductivity that differs from the first conductivity,
wherein each of the channel structures includes a first portion that penetrates through the stack structure in the vertical direction and a second portion that extends upward from the first portion, and
wherein the first material layer overlaps the second portion of the channel structures in the vertical direction, and the second material layer does not overlap the second portion of the channel structures in the vertical direction.

20. The semiconductor device of claim 19, further comprising:
a buffer layer disposed between the second material layer and the stack structure, between the second material layer and the second portion of the channel structures, and between the first material layer and the second portion of the channel structures,
wherein the first material layer includes a silicon layer that has a P-type conductivity,
wherein the second material layer includes a silicon layer that has an N-type conductivity, and
wherein the buffer layer includes an undoped silicon layer.
